(19) United States
(12) Patent Application Publication
(10) Pub. No.: US 2020/0194668 A1
(43) Pub. Date: Jun. 18, 2020

(54) INTERFACIAL RESISTIVE MEMORY GATE STACK TRANSISTOR CELL AND METHODS OF MANUFACTURING THE SAME

(71) Applicant: SANDISK TECHNOLOGIES LLC, Addison, TX (US)

(72) Inventor: Yoshihiro SATO, Nagoya (JP)

(21) Appl. No.: 16/220,554

(22) Filed: Dec. 14, 2018

(51) Int. Cl. H01L 45/00; H01L 27/24

(52) U.S. Cl. CPC H01L 45/1253; H01L 27/2454; H01L 45/146; H01L 45/08; H01L 45/1206; H01L 45/1683; H01L 45/1691; H01L 45/1675

(57) ABSTRACT

A resistive memory device includes at least one instance of a field effect transistor. The field effect transistor includes a semiconductor channel located between a source region and a drain region, and a gate stack. The gate stack includes a gate dielectric located on a surface of the semiconductor channel, a resistive memory material layer located on the gate dielectric, and a gate electrode containing a conductive material and located on the resistive memory material layer. The field effect transistors can be connected in a NAND configuration to provide three-dimensional and two-dimensional NAND resistive memory devices. Further, the field effect transistors can be connected as standalone devices to form a two-dimensional array of resistive memory devices.

### FIELD

The present disclosure relates generally to the field of semiconductor devices, and in particular to resistive memory devices using an interfacial resistive memory gate stack and methods of manufacturing the same.

### BACKGROUND

A resistive memory device refers to a memory device in which data is stored in the form of a resistive state of a resistive memory material. A resistive memory material refers to a material having at least two different resistive states. Resistive memory devices are non-volatile memory devices, and typically provide low power consumption, high operational speed, and high device density.

### SUMMARY

According to an aspect of the present disclosure, a resistive memory device comprising at least one instance of a field effect transistor is provided. The field effect transistor comprises: a semiconductor channel located between a source region and a drain region; and a gate stack comprising a gate dielectric located on a surface of the semiconductor channel, a resistive memory material layer located on the gate dielectric, and a gate electrode located on the resistive memory material layer and comprising a conductive material.

According to another aspect of the present disclosure, a method of forming a semiconductor structure is provided, which comprises: forming an alternating stack of insulating layers and sacrificial material layers over a substrate; forming a memory opening through the alternating stack; forming a sacrificial memory opening fill structure through the memory opening; forming backside recesses by removing the sacrificial material layers selective to the insulating layers; forming a resistive memory material layer and an electrically conductive layer within each backside recess; physically exposing sidewalls of the resistive memory material layers by removing the sacrificial memory opening fill structure; forming a gate dielectric on the sidewalls of the resistive memory material layers and on sidewalls of the insulating layers; and forming a vertical semiconductor channel on the gate dielectric.

### BRIEF DESCRIPTION OF THE DRAWINGS

FIG. 1A is a graph of a current-voltage characteristic of an interfacial resistive memory gate stack cell illustrated in FIG. 1B.

FIG. 1B is a cross-sectional view of an interfacial resistive memory gate stack cell according to an embodiment of the present disclosure.

FIG. 2 is a vertical cross-sectional view of an interfacial resistive memory gate stack field effect transistor according to an embodiment of the present disclosure.

FIG. 3 is graph of an exemplary current-voltage characteristics of the interfacial resistive memory gate stack field effect transistor of FIG. 2.

FIG. 4 is a graph illustrating the dependence of the threshold voltage and the gate capacitance as a function of gate resistance for the interfacial resistive memory gate stack field effect transistor of FIG. 2.

FIG. 5 is a graph illustrating variations in the current-voltage characteristic of the interfacial resistive memory gate stack field effect transistor of FIG. 2 in response to changes in the reset voltage.

FIGS. 6A-6C are vertical cross-sectional views of an interfacial resistive memory gate stack field effect transistor illustrating bias schemes during a reset operation, a set operation, and a read operation, respectively.

FIGS. 7A-7F are sequential vertical cross-sectional views of a first exemplary structure during manufacture of the interfacial resistive memory gate stack field effect transistor of FIG. 2.

FIG. 8 is a circuit diagram for a two-dimensional or three-dimensional resistive memory array device including interfacial resistive memory gate stack transistor cells according to an embodiment of the present disclosure.

FIG. 9 is a circuit diagram for a two-dimensional field effect transistor resistive memory array device according to an embodiment of the present disclosure.

FIG. 10 is a circuit diagram for a two-dimensional or three-dimensional NAND resistive memory array device according to an embodiment of the present disclosure.

FIG. 11A is a vertical cross-sectional view of a vertical NAND string that can be used to form a three-dimensional resistive memory array device according to an embodiment of the present disclosure.

FIG. 11B is a perspective view of the vertical NAND string of FIG. 11A.

FIG. 12A and FIG. 12B are schematic views of two embodiments of a three-dimensional NAND resistive memory array device according to an embodiment of the present disclosure.

FIG. 13 is a vertical cross-sectional view of a second exemplary structure after formation of at least one peripheral device, a semiconductor material layer, and an alternating stack of insulating layers and sacrificial material layers according to an embodiment of the present disclosure.

FIG. 14 is a schematic vertical cross-sectional view of the second exemplary structure after formation of stepped terraces and a retro-stepped dielectric material portion according to an embodiment of the present disclosure.

FIG. 15A is a schematic vertical cross-sectional view of the second exemplary structure after formation of memory openings and support openings according to an embodiment of the present disclosure.

FIG. 15B is a top-down view of the exemplary structure of FIG. 15A. The vertical plane A-A′ is the plane of the cross-section for FIG. 15A.

FIG. 16 is a schematic vertical cross-sectional view of the second exemplary structure after formation of dielectric liner structures according to an embodiment of the present disclosure.

FIG. 17 is a schematic vertical cross-sectional view of the second exemplary structure after formation of sacrificial memory opening fill structures according to an embodiment of the present disclosure.

FIG. 18A is a schematic vertical cross-sectional view of the second exemplary structure after formation of backside trenches according to an embodiment of the present disclosure.

FIG. 18B is a partial see-through top-down view of the second exemplary structure of FIG. 18A. The vertical plane A-A′ is the plane of the schematic vertical cross-sectional view of FIG. 18A.

FIG. 19 is a schematic vertical cross-sectional view of the second exemplary structure after formation of backside recesses according to an embodiment of the present disclosure.

FIG. 20 is a schematic vertical cross-sectional view of the second exemplary structure after formation of resistive memory material layers and electrically conductive layers according to an embodiment of the present disclosure.

FIG. 21 is a schematic vertical cross-sectional view of the second exemplary structure after formation of an insulating spacer and a backside contact structure according to an embodiment of the present disclosure.

FIG. 22 is a schematic vertical cross-sectional view of the second exemplary structure after removal of the sacrificial memory opening fill structures and the dielectric liner structures according to an embodiment of the present disclosure.

FIG. 23 is a schematic vertical cross-sectional view of the second exemplary structure after formation of gate dielectric layers according to an embodiment of the present disclosure.

FIG. 24 is a schematic vertical cross-sectional view of the second exemplary structure after formation of memory opening fill structures according to an embodiment of the present disclosure.

FIG. 25A is a schematic vertical cross-sectional view of the second exemplary structure after formation of additional contact via structures according to an embodiment of the present disclosure.

FIG. 25B is a top-down view of the exemplary structure of FIG. 25A. The vertical plane A-A′ is the plane of the schematic vertical cross-sectional view of FIG. 25A.

### DETAILED DESCRIPTION

As discussed above, the embodiments of the present disclosure are directed to three-dimensional memory devices including resistive memory devices using an interfacial resistive memory gate stack and methods of making thereof, the various aspects of which are described below. Resistive memory devices typically provide low power consumption, high operational speed, and high device density. However, device scaling of resistive memory devices is limited by low read current. For example, a two-terminal resistive memory cell including a first electrode, an oxygen ion and/or vacancy modulated metal oxide that functions as a resistive memory element, and a second electrode and having a size of about 40 square nanometers provides a typical read current of 20 nA in a low resistive state, which is difficult to sense with normal sense amplifiers. Various embodiments of the present disclosure provide resistive memory devices capable of providing a high read current, thus providing the advantages of resistive memory devices that are scalable. The embodiments of the disclosure can be used to form various structures including a multilevel memory structure, non-limiting examples of which include semiconductor devices such as three-dimensional monolithic memory array devices comprising a plurality of NAND memory strings.

The drawings are not drawn to scale. Multiple instances of an element may be duplicated where a single instance of the element is illustrated, unless absence of duplication of elements is expressly described or clearly indicated otherwise. Ordinals such as “first,” “second,” and “third” are used merely to identify similar elements, and different ordinals may be used across the specification and the claims of the instant disclosure. The same reference numerals refer to the same element or similar element. Unless otherwise indicated, elements having the same reference numerals are presumed to have the same composition. Unless otherwise indicated, a “contact” between elements refers to a direct contact between elements that provides an edge or a surface shared by the elements. As used herein, a first element located “on” a second element can be located on the exterior side of a surface of the second element or on the interior side of the second element. As used herein, a first element is located “directly on” a second element if there exist a physical contact between a surface of the first element and a surface of the second element. As used herein, a “prototype” structure or an “in-process” structure refers to a transient structure that is subsequently modified in the shape or composition of at least one component therein.

As used herein, a “layer” refers to a material portion including a region having a thickness. A layer may extend over the entirety of an underlying or overlying structure, or may have an extent less than the extent of an underlying or overlying structure. Further, a layer may be a region of a homogeneous or inhomogeneous continuous structure that has a thickness less than the thickness of the continuous structure. For example, a layer may be located between any pair of horizontal planes between, or at, a top surface and a bottom surface of the continuous structure. A layer may extend horizontally, vertically, and/or along a tapered surface. A substrate may be a layer, may include one or more layers therein, or may have one or more layer thereupon, thereabove, and/or therebelow.

As used herein, a “semiconducting material” refers to a material having electrical conductivity in the range from 1.0×10⁻⁶ S/cm to 1.0×10⁵ S/cm. As used herein, a “semiconductor material” refers to a material having electrical conductivity in the range from 1.0×10⁻⁶ S/cm to 1.0×10⁵ S/cm in the absence of electrical dopants therein, and is capable of producing a doped material having electrical conductivity in a range from 1.0 S/cm to 1.0×10⁵ S/cm upon suitable doping with an electrical dopant. As used herein, an “electrical dopant” refers to a p-type dopant that adds a hole to a valence band within a band structure, or an n-type dopant that adds an electron to a conduction band within a band structure. As used herein, a “conductive material” refers to a material having electrical conductivity greater than 1.0×10⁵ S/cm. As used herein, an “insulator material” or a “dielectric material” refers to a material having electrical conductivity less than 1.0×10⁻⁶ S/cm. As used herein, a “heavily doped semiconductor material” refers to a semiconductor material that is doped with electrical dopant at a sufficiently high atomic concentration to become a conductive material either as formed as a crystalline material or if converted into a crystalline material through an anneal process (for example, from an initial amorphous state), i.e., to have electrical conductivity greater than 1.0×10⁵ S/cm. A “doped semiconductor material” may be a heavily doped semiconductor material, or may be a semiconductor material that includes electrical dopants (i.e., p-type dopants and/or n-type dopants) at a concentration that provides electrical conductivity in the range from 1.0×10⁻⁶ S/cm to 1.0×10⁵ S/cm. An “intrinsic semiconductor material” refers to a semiconductor material that is not doped with electrical dopants. Thus, a semiconductor material may be semiconducting or conductive, and may be an intrinsic semiconductor material or a doped semiconductor material. A doped semiconductor material can be semiconducting or conductive depending on the atomic concentration of electrical dopants therein. As used herein, a “metallic material” refers to a conductive material including at least one metallic element therein. All measurements for electrical conductivities are made at the standard condition.

A monolithic three-dimensional memory array is one in which multiple memory levels are formed above a single substrate, such as a semiconductor wafer, with no intervening substrates. The term “monolithic” means that layers of each level of the array are directly deposited on the layers of each underlying level of the array. In contrast, two dimensional arrays may be formed separately and then packaged together to form a non-monolithic memory device. For example, non-monolithic stacked memories have been constructed by forming memory levels on separate substrates and vertically stacking the memory levels, as described in U.S. Pat. No. 5,915,167 titled “Three-dimensional Structure Memory.” The substrates may be thinned or removed from the memory levels before bonding, but as the memory levels are initially formed over separate substrates, such memories are not true monolithic three-dimensional memory arrays. The various embodiments of three-dimensional memory devices include a monolithic three-dimensional NAND string memory device, and can be fabricated using the various embodiment methods described herein.

Generally, a semiconductor die, or a semiconductor package, can include a memory chip. Each semiconductor package contains one or more dies (for example one, two, or four). The die is the smallest unit that can independently execute commands or report status. Each die contains one or more planes (typically one or two). Identical, concurrent operations can take place on each plane, although with some restrictions. Each plane contains a number of blocks, which are the smallest unit that can be erased by in a single erase operation. Each block contains a number of pages, which are the smallest unit that can be programmed, i.e., a smallest unit on which a read operation can be performed.

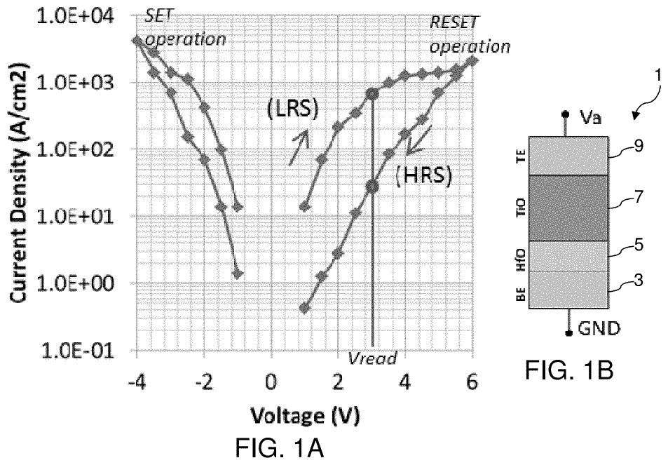

FIG. 1A is a current-voltage characteristic of an interfacial resistive memory gate stack cell 1 illustrated in FIG. 1B according to an embodiment of the present disclosure. The interfacial resistive memory gate stack cell 1 includes a pseudo-gate stack including a bottom electrode (BE) 3, a hafnium oxide (HfO) portion 5, a titanium oxide (TiO) portion 7, and a top electrode (TE) 9 including a first metal. The hafnium oxide portion 5 functions as an equivalent of a gate dielectric, the titanium oxide portion 7 functions a variable resistance gate electrode that changes resistance depending on the programmed state, and the top electrode 9 functions as a conductive gate electrode having high electrical conductivity. The hafnium oxide portion 5 comprises, and/or consists essentially of, hafnium oxide, and can have a thickness in a range from 1 nm to 6 nm, such as from 1.5 nm to 4 nm. The titanium oxide portion 7 comprises, and/or consists essentially of, titanium oxide, and can have a thickness in a range from 3 nm to 30 nm, such as from 6 nm to 15 nm, although lesser and greater thicknesses can also be used. The top electrode 9 can include a metallic material such as TiN, TaN, WN, an elemental metal, or an intermetallic alloy. The interfacial resistive gate memory stack 1 bottom electrode 3 includes a conductive material that may be implemented as a semiconductor channel in some embodiments of the present disclosure. The bottom electrode 3 can include a metallic material such as TiN, TaN, WN, an elemental metal, or an intermetallic alloy, or can include a doped semiconductor material such as epitaxial silicon or polysilicon.

The bottom electrode 3 can be electrically grounded, and a variable applied voltage Va can be applied to the top electrode. The titanium oxide portion 7 can transition from a low resistance state (LRS) to a high resistance state (HRS) by applying a positive voltage to the top electrode 9 in a reset operation, and can transition from the high resistance state to the low resistance state by applying a negative voltage to the top electrode 9 in a reset operation. The resistive state of the titanium oxide 7 portion can be read by applying a low positive voltage to the top electrode 9 and measuring the magnitude of the electrical current that passes between the top electrode 9 and the bottom electrode 3. Current ratios greater than 10 can be achieved between the low resistivity state read current and the high resistivity state read current.

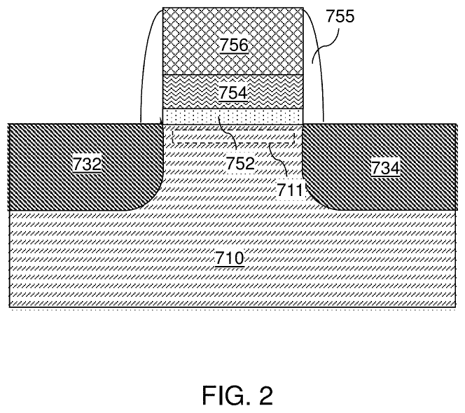

Referring to FIG. 2, an interfacial resistive memory gate stack field effect transistor is illustrated, which incorporates an embodiment of the interfacial resistive memory gate stack cell 1 of FIG. 1 according to an embodiment of the present disclosure. The interfacial resistive memory gate stack field effect transistor includes a field effect transistor including an interfacial resistive memory gate stack (752, 754, 756). The interfacial resistive memory gate stack (752, 754, 756) is located on a semiconductor channel 711 located in a surface portion of a body region 710 and between a source region 732 and a drain region 734.

The body region 710, the source region 732, and the drain region 734 can be located within a semiconductor material layer (which may be a semiconductor substrate or may be located in an upper portion of a substrate). The body region 710 has a doping of a first conductivity type, and the source region 732 and the drain region 734 have a doping of a second conductivity type that is the opposite of the first conductivity type. The atomic concentration of electrical dopants of the first conductivity type in the body region 710 can be in a range from 1.0×10¹⁴/cm³ to 3.0×10¹⁸/cm³, although lesser and greater atomic concentrations can also be used. The atomic concentration of electrical dopants of the second conductivity type in the source region 732 and the drain region 734 can be in a range from 3.0×10¹⁹/cm³ to 2.0×10²¹/cm³, although lesser and greater atomic concentrations can also be used.

The interfacial resistive memory gate stack (752, 754, 756) includes a gate dielectric 752, a resistive memory material layer 754 located on the gate dielectric 752, and a gate electrode 756 comprising a conductive material (such as a metallic material) and located on the resistive memory material layer 754. The gate dielectric 752 includes at least one dielectric material layer such as a silicon oxide layer, a dielectric metal oxide layer, or a stack thereof. The composition and thickness of the gate dielectric 752 are selected such that charge tunneling can occur through the gate dielectric 752 to enable flow of electrical current therethrough. The thickness of the gate dielectric 752 can be in a range from 1 nm to 6 nm, such as from 1.5 nm to 4 nm, although lesser and greater thicknesses can also be used.

The resistive memory material layer 754 includes a resistive memory material. As used herein, a “resistive memory material” or a “reversibly resistance-switching material” is a material of which the resistivity can be altered by application of a voltage across the material. As used herein, a “resistive memory material layer” refers to a layer including a resistive memory material. As used herein, a “resistive memory element” refers to an element that includes a portion of a resistive memory material in a configuration that supports programming of the resistive memory material into at least two states having different values of electrical resistance. In one embodiment, the resistive memory material in the resistive memory material layer 754 can include an electrically conductive metal oxide whose resistivity is switched by at least one of oxygen ion and/or oxygen vacancy diffusion in response to an application of an electric field thereto. The resistive memory material layer 754 can be a part of a non-filamentary barrier modulated cell (BMC), which also includes a barrier (e.g., such as the gate electrode material 756). The density of oxygen ions and/or vacancies in the resistive memory material layer 754 material can be modulated (i.e., changed) by applying an external electrical field. In one embodiment, the resistive memory material layer 754 can comprise, and/or can consist essentially of, a titanium oxide material including oxygen vacancies. In one embodiment, the resistive memory material layer 754 can include oxygen-deficient titanium oxide having the formula of TiO_{2-δ}, in which δ is in a range from 0 to 0.3. The thickness of the resistive memory material layer 754 can be in a range from 3 nm to 30 nm, such as from 6 nm to 15 nm, although lesser and greater thicknesses can also be used.

The gate electrode 756 can include a metallic material such as TiN, TaN, WN, an elemental metal, or an intermetallic alloy. In one embodiment, the gate electrode 756 can comprise, and/or can consist essentially of, TiN. In one embodiment, the thickness of the gate electrode 756 can be in a range from 20 nm to 200 nm, although lesser and greater thicknesses can also be used.

The semiconductor channel 711 in the body region 710 of the interfacial resistive memory gate stack field effect transistor functions as a bottom electrode of the interfacial resistive memory gate stack cell 1 of FIG. 1. The interfacial resistive memory gate stack (752, 754, 756) of the interfacial resistive memory gate stack field effect transistor functions as the pseudo-gate of the interfacial resistive memory gate stack cell of FIG. 1. In one embodiment, each of the gate dielectric 752, the resistive memory material layer 754, and the gate electrode 756 can extend along the semiconductor channel 711 from an edge of the source region 732 to an edge of the drain region 734. A dielectric gate spacer 755 can laterally surround the interfacial resistive memory gate stack (752, 754, 756).

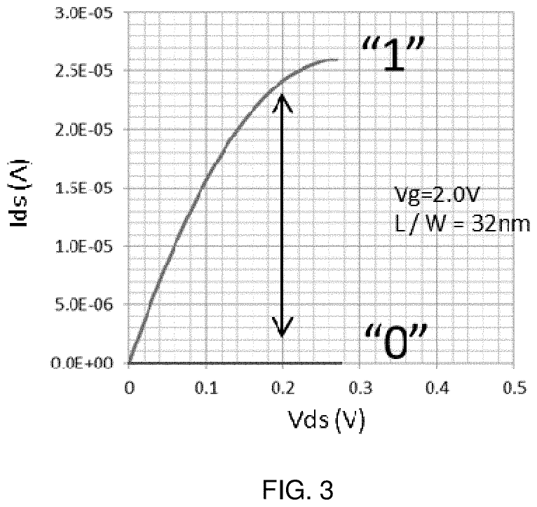

FIG. 3 is a graph of exemplary current-voltage characteristics determined in a simulation of the interfacial resistive memory gate stack field effect transistor of FIG. 2. In the simulation, the area of contact between the semiconductor channel 711 and the gate dielectric 752 had the size of 32 nm×32 nm, i.e., had a square area with the length of each side at 32 nm. In the simulation, the gate dielectric 752 was a 2.5 nm thick hafnium oxide, and the resistive memory material layer 754 was a 10 nm thick titanium oxide.

The interfacial resistive memory gate stack field effect transistor provides two distinct current-voltage characteristics corresponding to the two resistive states of the resistive memory material layer 754. The high resistive state of the resistive memory material layer 754 provides a current-voltage characteristic labeled “0,” in which no (or minimal) electrical current flows for the gate bias voltage of 2.0 V applied to the gate electrode 756 and for a drain-to-source bias voltage range from 0 V to 2.8 V. In this case, a predominant fraction (i.e., more than 50%) of the gate bias voltage is applied across the resistive memory material layer 754 due to the high resistance of the resistive memory material layer 754, and only a small fraction of the gate bias voltage is present at an interface between the resistive memory material layer 754 and the gate dielectric 752. If the voltage at the interface between the resistive memory material layer 754 and the gate dielectric 752 is less than the threshold voltage required to turn on the semiconductor channel 711 of the field effect transistor, the drain-to-source current is zero (or minimal) irrespective of the drain-to-source bias voltage applied across the source region 732 and the drain region 734.

The low resistive state of the resistive memory material layer 754 provides a current-voltage characteristic labeled “1,” in which the source-to-drain current flows for the gate bias voltage of 2.0 V applied to the gate electrode 756 and for a positive drain-to-source bias voltage. In this case, only a small fraction (i.e., less than 50%, such as less than 20%) of the gate bias voltage is applied across the resistive memory material layer 754 due to the low resistance of the resistive memory material layer 754, and a predominant fraction of the gate bias voltage is present at an interface between the resistive memory material layer 754 and the gate dielectric 752. If the voltage at the interface between the resistive memory material layer 754 and the gate dielectric 752 is greater than the threshold voltage required to turn on the semiconductor channel 711 of the field effect transistor, the drain-to-source current increases with the drain-to-source bias voltage applied across the source region 732 and the drain region 734.

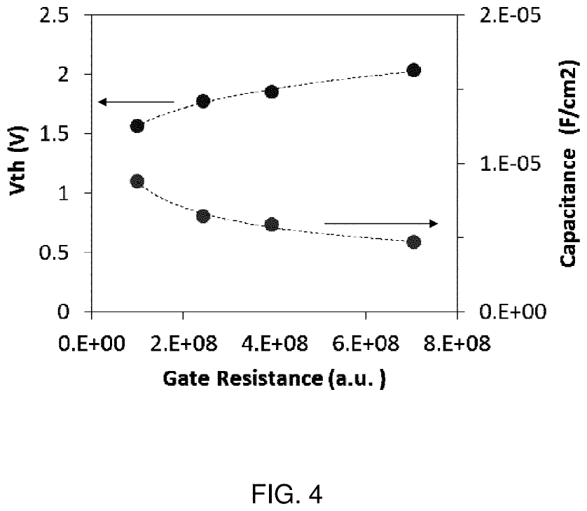

FIG. 4 illustrates the dependence of the threshold voltage and the gate capacitance as a function of gate resistance for the interfacial resistive memory gate stack field effect transistor of FIG. 2. If the resistive memory material layer 754 is in a low resistance state, the capacitance between the semiconductor channel 711 and the gate electrode 756 approaches the capacitance of a parallel plate capacitor in which the gate dielectric 752 alone functions as a node dielectric, thereby providing a large capacitance. If the resistive memory material layer 754 is in a high resistance state, the capacitance between the semiconductor channel 711 and the gate electrode 756 approaches the capacitance of a parallel plate capacitor in which the gate dielectric 752 and the high-resistance material of the resistive memory material layer 754 collectively function as a node dielectric, thereby providing a small capacitance. The variable capacitance of the interfacial resistive memory gate stack (752, 754, 756) has an effect on the effective threshold voltage Vth, which is the minimum gate bias voltage for the gate electrode 756 that is necessary to turn on the semiconductor channel 711. The effective threshold voltage Vth decreases with the resistance of the resistive memory material layer 754.

The effective threshold voltage required to turn on the semiconductor channel 711 when the resistive memory material layer 754 is in a low resistance state is herein referred to as a low resistance state threshold voltage. The effective threshold voltage required to turn on the semiconductor channel 711 when the resistive memory material layer 754 is in a high resistance state is herein referred to as a high resistance state threshold voltage. The low resistance state threshold voltage is lower than the high resistance state threshold voltage. When the gate bias voltage applied to the gate electrode 756 is between the low resistance state threshold voltage and the high resistance threshold voltage, the semiconductor channel 711 turns on if resistive memory material layer 754 is in a low resistance state, and turns off if the resistive memory material layer 754 is in a high resistance state. Thus, one of the current-voltage characteristics represented by “0” and “1” in FIG. 3 is manifested by the interfacial resistive memory gate stack field effect transistor of various embodiments of the present disclosure depending on the resistive state of the resistive memory material layer 754. In other words, the resistive state of the resistive memory material layer 754 modulates the transistor characteristics of the interfacial resistive memory gate stack field effect transistor of the various embodiments.

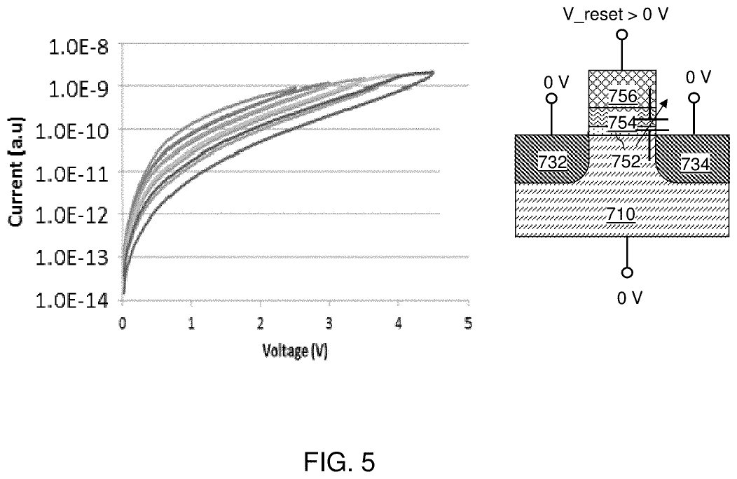

Referring to FIG. 5, operation of the interfacial resistive memory gate stack field effect transistor of FIG. 2 during a reset operation is illustrated. In this case, the semiconductor channel in the body region 710 can be electrically grounded, for example, by applying 0 V to the source region 732 and the drain region 734. Optionally, the body region 710 may be directly biased by a backside contact to which 0 V is applied. A positive reset voltage V_reset can be applied to the gate electrode 756. In one embodiment, the positive reset voltage V_reset can be varied to 0 V to a positive voltage at which the tunneling current through the interfacial resistive memory gate stack (752, 754, 756) reaches a predetermined threshold level that will cause a programmed of the resistive memory material layer 754. The current-voltage characteristics for the reset operation can depend on the resistive state of the resistive memory material layer 754 before the reset operation. The various current-voltage characteristics for the reset operation is illustrated as multiple current-voltage characteristic curves in FIG. 5. Depending on the previous resistive state of the resistive memory material layer 754, a maximum reset voltage for the reset operation may be in a range from 2.5 V to 4.5 V.

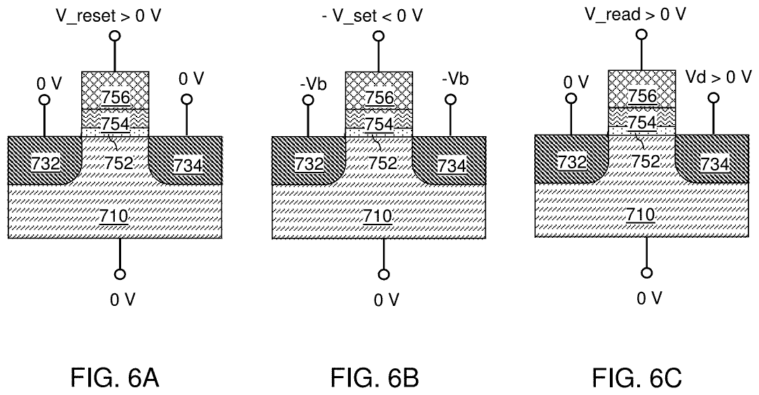

FIGS. 6A-6C illustrate bias schemes for the interfacial resistive memory gate stack field effect transistor of FIG. 2 during a reset operation, a set operation, and a read operation, respectively.

Referring to FIG. 6A, the reset operation of the interfacial resistive memory gate stack field effect transistor of FIG. 2 can be performed by applying a positive reset bias voltage V_reset to the gate electrode 756, while applying 0 V to the source region 732, the drain region 734, and the optional backside contact connected to the body region 710. The positive reset voltage for the reset operation can be selected to induce the change of the resistive state of the resistive memory material layer 754 to the high resistance state irrespective of the prior resistive state of the resistive memory material layer 754. The positive reset bias voltage V_reset can be in a range from 2.5 V to 10 V, such as from 3 V to 7 V, although lesser and greater positive voltages can also be used. In case the resistive memory material layer 754 includes a non-filamentary electrically conductive metal oxide whose resistivity is switched by at least one of oxygen ion and/or oxygen vacancy diffusion in response to an application of an electric field thereto, then in one embodiment oxygen vacancies in the resistive memory material layer 754 drift toward the gate electrode 756, thereby increasing the resistance of the resistive memory material layer 754.

Referring to FIG. 6B, the set operation of the interfacial resistive memory gate stack field effect transistor of FIG. 2 can be performed by applying a negative set bias voltage −V_set to the gate electrode 756, while applying a negative active region bias voltage −Vb to the source region 732, the drain region 734, and applying 0 V to the optional backside contact connected to the body region 710. The negative set voltage for the set operation can be selected to induce the change of the resistive state of the resistive memory material layer 754 to the low resistance state irrespective of the prior resistive state of the resistive memory material layer 754. The negative set bias voltage −V_set can be in a range from −9 V to −2 V, such as from −6 V to −2.5 V, although lesser and greater negative voltages can also be used. The negative active region bias voltage −Vb can be in a range from −1.0 V to −0.1 V, although lesser and greater negative active region bias voltages can also be used. In case the resistive memory material layer 754 includes a non-filamentary electrically conductive metal oxide whose resistivity is switched by at least one of oxygen ion and/or oxygen vacancy diffusion in response to an application of an electric field thereto, then in one embodiment oxygen vacancies in the resistive memory material layer 754 drift away from the gate electrode 756 toward the gate dielectric 752, thereby reducing the resistance of the resistive memory material layer 754.

Referring to FIG. 6C, the read operation of the interfacial resistive memory gate stack field effect transistor of FIG. 2 can be performed by applying a positive read bias voltage V_read to the gate electrode 756, while applying 0 V to the source region 732 and the optional backside contact connected to the body region 710, and applying a positive drain read bias voltage Vd to the drain region 734. The positive read voltage for the read operation can be selected as a low positive voltage that does not induce any change of the resistive state of the resistive memory material layer 754. The positive read bias voltage V_read can be in a range from 1 V to 5 V, such as from 1.5 V to 4 V, although lesser and greater positive voltages can also be used.

Generally, a resistive memory device includes at least one instance of the interfacial resistive memory gate stack field effect transistor of FIG. 2. Each semiconductor channel 711 can be a horizontal semiconductor channel or a vertical semiconductor channel. Each semiconductor channel 711 can be provided between a respective pair of a source region 732 and a drain region 734, or within a string of multiple semiconductor channels 711 between a source region 732 and a drain region 734 in a NAND string. An instance of the interfacial resistive memory gate stack field effect transistor of FIG. 2 can be selected for programming. The resistive memory material layer 756 of the selected instance can be programmed into a resistive state selected from a reset state and a set state. The resistive memory material layer 754 has a higher resistance and provides a lower capacitance between the gate electrode 756 and the semiconductor channel 711 in a reset state than in a set state. For each selected instance of the interfacial resistive memory gate stack field effect transistor of FIG. 2, the resistive state of the resistive memory material layer 754 can be determined by measuring a magnitude of a source-to-drain current under a predetermined drain bias voltage to the drain region 734 and under a predetermined read bias voltage to the gate electrode 756.

In one embodiment, the resistive memory material layer 754 can be programmed into the reset state by applying a more positive voltage to the gate electrode 756 than a voltage applied to the semiconductor channel 711 while the source region 732 and the drain region 734 are biased at a same active region bias voltage (such as 0 V). In one embodiment, the resistive memory material layer 734 can be programmed into the set state by applying a more negative voltage to the gate electrode 756 than a voltage applied to the semiconductor channel 711 while the source region 732 and the drain region 734 are biased at a same active region bias voltage (such as the negative active region bias voltage −Vb).

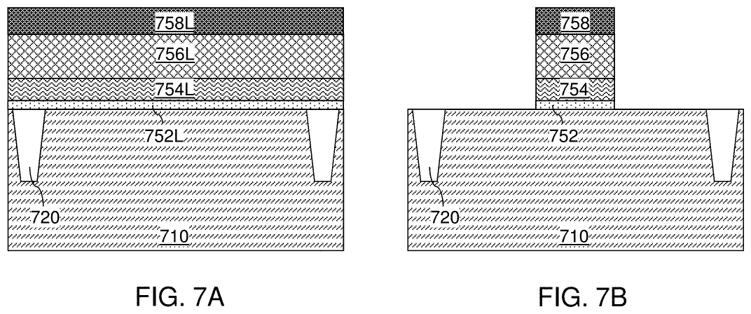

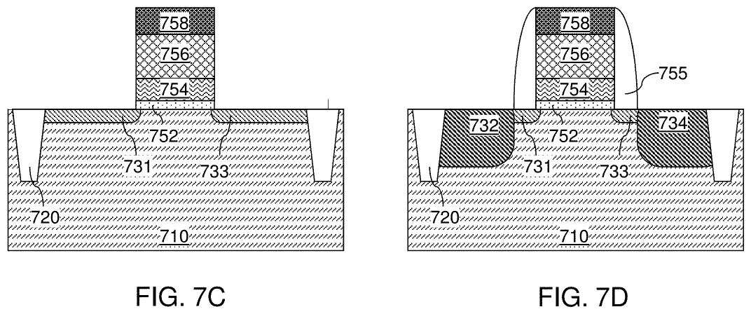

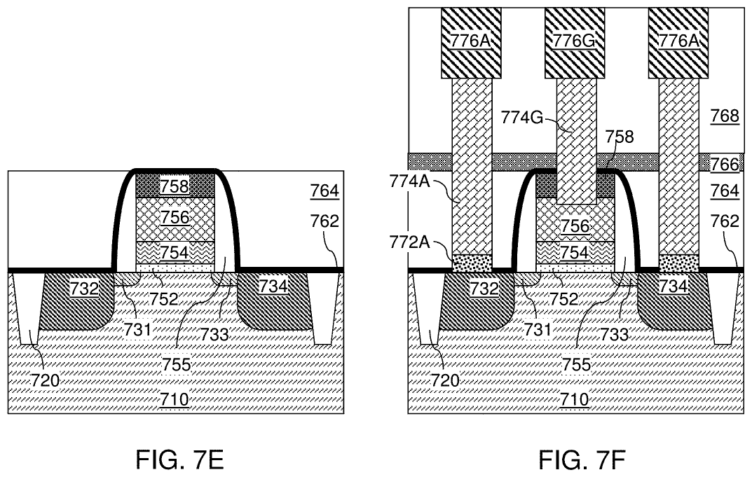

FIGS. 7A-7F illustrate sequential vertical cross-sectional views of a first exemplary structure during manufacture of the interfacial resistive memory gate stack field effect transistor of FIG. 2 using a method of manufacturing according an embodiment of the present disclosure. The first exemplary structure embodies an instance of the interfacial resistive memory gate stack field effect transistor of FIG. 2 as a discrete field effect transistor including a horizontal semiconductor channel.

Referring to FIG. 7A, a semiconductor material layer can be provided on, or in, a substrate. The semiconductor material layer includes a surface region, which is used as a body region 710 for the interfacial resistive memory gate stack field effect transistor to be subsequently formed. The semiconductor material layer including the body region 710 can have a doping of a first conductivity type, which may be p-type or n-type. Shallow trench isolation structures 720 can be formed in the upper portion of the semiconductor material layer to provide electrical isolation between various surface portions of the semiconductor material layer.

A continuous gate dielectric layer 752L, a continuous resistive memory material layer 754L, a continuous gate electrode material layer 756L, and a continuous gate cap dielectric layer 758L can be sequentially formed on the top surface of the semiconductor material layer. The continuous gate dielectric layer 752L can have the same material composition and the same thickness as the gate dielectric 752 of the interfacial resistive memory gate stack field effect transistor of FIG. 2. The continuous resistive memory material layer 754L can have the same material composition and the same thickness as the resistive memory material layer 754 of the interfacial resistive memory gate stack field effect transistor of FIG. 2. The continuous gate electrode material layer 756L can have the same material composition and the same thickness as the gate electrode 756 of the interfacial resistive memory gate stack field effect transistor of FIG. 2. The continuous gate cap dielectric layer 758L can include a dielectric material such as silicon nitride or silicon oxide, and can have a thickness in a range from 20 nm to 80 nm, although lesser and greater thicknesses can also be used.

Referring to FIG. 7B, the gate stack layers including the continuous gate dielectric layer 752L, the continuous resistive memory material layer 754L, the continuous gate electrode material layer 756L, and the continuous gate cap dielectric layer 758L can be patterned to form gate stacks. For example, a photoresist layer (not shown) can be applied over the continuous gate cap dielectric layer 758L, and can be lithographically patterned to cover discrete areas. Unmasked portions of the gate stack layers can be anisotropically etched using the semiconductor material layer as an etch stop layer. Each patterned portion of the gate stack layers constitute a gate stack, which can include, from bottom to top, a gate dielectric 752, a resistive memory material layer 754, a gate electrode 756, and a gate cap dielectric 758.

Referring to FIG. 7C, extension regions (731, 732) can be formed by implanting dopants of a second conductivity type into surface portions of the semiconductor material layer that are not covered by the gate stacks (752, 754, 756, 758). The second conductivity type if the opposite of the first conductivity type. For example, if the first conductivity type is p-type, the second conductivity type is n-type, and vice versa. The extension regions (731, 733) can include a source extension region 731 and a drain extension region 733.

Referring to FIG. 7D, a dielectric gate spacer 755 can be formed on sidewalls of each gate stack (752, 754, 756, 758). For example, a conformal dielectric material layer can be deposited over the gate stacks (752, 754, 756, 758) and the semiconductor material layer, and an anisotropic etch process can be performed to remove horizontal portions of the conformal dielectric material layer. Each remaining portion of the conformal dielectric material layer constitutes a dielectric gate spacer 755. In one embodiment, the dielectric gate spacer 755 can be homeomorphic to a torus, i.e., may be continuously stretched into the shape of a torus without creating or destroying a hole. Additional dopants of the second conductivity type can be implanted into portions of the semiconductor material layer that are not masked by the gate stacks (752, 754, 756, 758) and the dielectric gate spacers 755. Active regions (732, 734) can be formed in regions of the semiconductor material layer that are implanted with the additional dopants of the second conductivity type. The active regions (732, 734) can include source regions 732 and drain regions 734. Each source region 732 can be adjoined to a source extension region 731, and each drain region 734 can be adjoined to a drain extension region 733.

Referring to FIG. 7E, a dielectric liner 762 can be deposited over the gate stacks (752, 754, 756, 758) and the semiconductor material layer by a conformal deposition process. The dielectric liner 732 can include silicon oxide, silicon nitride, or a layer stack thereof. A planarization dielectric layer 764 can be formed over the dielectric liner 762 by deposition of a planarizable dielectric material (such as silicon oxide) or a self-planarizing dielectric material (such as a flowable oxide (FOX)). The planarization dielectric layer 764 may be planarized by chemical mechanical planarization using portions of the dielectric liner 762 overlying the gate stacks (752, 754, 756, 758) as planarization stopping structures.

Referring to FIG. 7F, interconnect dielectric material layers (766, 768) can be formed over the planarization dielectric layer 764. The interconnect dielectric material layers (766, 768) can include, for example, a silicon nitride etch stop layer 766 and at least one dielectric material layer 768, which may include a vertical stack of a contact level dielectric layer and a line level dielectric layer. Contact via cavities can be formed through the interconnect dielectric material layers (766, 768). Metal semiconductor alloy portions 772A can be formed on top surfaces of the active regions (732, 734) underneath each contact via cavity that overlies the active regions (732, 734). Contact via structures (774A, 774G) can be formed in the contact via cavities. The contact via structures (774A, 774G) can include active region contact via structures 774A that contact a respective one of the active regions (732, 734) and gate contact via structures 774G that contacts a respective gate electrode 756. Interconnect line structures (776A, 776G) can be formed within the additional dielectric material layer (766, 768) directly on the contact via structures (774A, 774G). The interconnect line structures (776A, 776G) can include active region interconnect line structures 776A that contacts a top surface of an active region contact via structure 774A, and gate electrode interconnect line structures 776G that contacts a top surface a gate contact via structure 774G. Additional interconnect dielectric material layers and additional metal interconnect structures can be formed as needed.

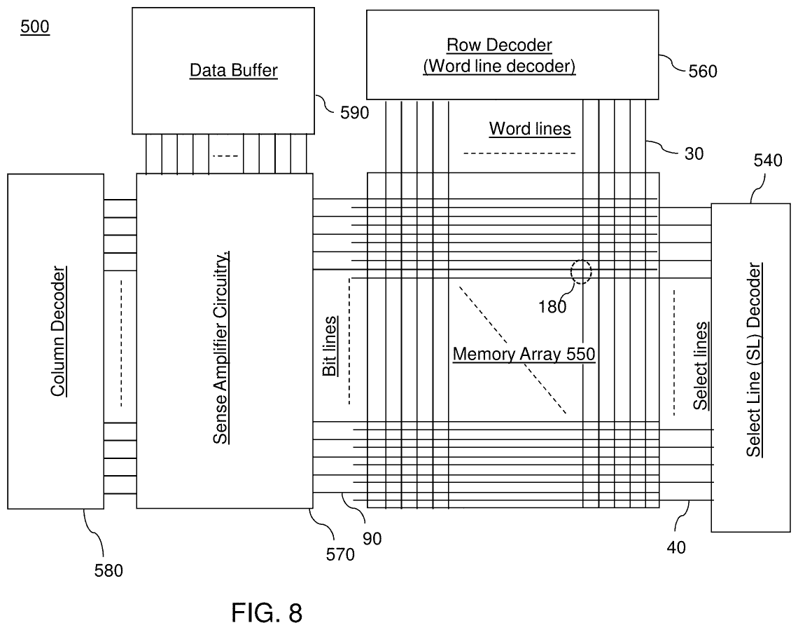

Referring to FIG. 8, a schematic diagram is shown for a two-dimensional or three-dimensional resistive memory array device including interfacial resistive memory gate stack transistor cells 180 of the various embodiments in an array configuration. Each interfacial resistive memory gate stack transistor cell 180 can include an instance of the interfacial resistive memory gate stack field effect transistor of FIG. 2 or FIG. 7F, or an instance of three-dimensional resistive memory cell to be described below. The resistive memory array device can be configured as a random access memory device 500. As used herein, a “random access memory device” refers to a memory device including memory cells that allow random access, i.e., access to any selected memory cell upon a command for reading the contents of the selected memory cell.

The random access memory device 500 of the various embodiments includes a memory array region 550 containing an array of the respective resistive memory cells 180 located at the intersection of the respective word lines (which may comprise first electrically conductive lines 30 as illustrated or second electrically conductive lines 90 in an alternate configuration) and bit lines (which may comprise second electrically conductive lines 90 as illustrated or first electrically conductive lines 30 in an alternate configuration). Select lines may comprise third electrically conductive lines 40. In one embodiment, the select lines may be used to enable selection of a group of interfacial resistive memory gate stack transistor cells 180 among groups of interfacial resistive memory gate stack transistor cells 180 connected to a same set of word lines and a same set of bit lines. Alternatively, the select lines may be used in conjunction with the bit lines to select a column of interfacial resistive memory gate stack transistor cells 180 accessed by different word lines.

The random access memory device 500 may also contain a row decoder 560 connected to the word lines, a sense circuitry 570 (e.g., a sense amplifier and other bit line control circuitry) connected to the bit lines, a column decoder 580 connected to the bit lines, a select line decoder 540 connected to select lines, and a data buffer 590 connected to the sense circuitry. Each word line can be connected to a plurality of gate electrodes 756 arranged along a first direction, and can be a single first electrically conductive line 30. Each bit line can be connected to a plurality of drain regions 734 arranged along a second direction that is different from the first direction, and can be a single second electrically conductive line 90. The sense circuitry may include the same number of sense amplifiers as the number of bit lines, and thus, may be configured to sense the resistive state of all resistive memory cells 180 connected to a selected word line for each of the bit lines connected to the sense amplifier circuitry. Alternatively, the sense circuitry may include a single sense amplifier, and a bit line selector may be provided in the sense circuitry such that the resistive state of a single resistive memory cell 180 determined by the selected word line and the selected bit line can be sensed at a time.

Multiple instances of the resistive memory cells 180 are provided in an array configuration that forms the random access memory device 500. As such, each of the resistive memory cells 180 can be a three-terminal device including a respective first electrode that is a gate electrode 756, a respective second electrode connected to a drain region 734, and a respective third electrode connected to a source region 732. A backside bias voltage can be applied to a backside electrode connected to the body region 710, i.e., the semiconductor material layer embedding the semiconductor channels 711, of the semiconductor material layer. It should be noted that the location and interconnection of elements are schematic and the elements may be arranged in a different configuration. Further, a resistive memory cell 180 may be manufactured as a discrete device, i.e., a single isolated device.

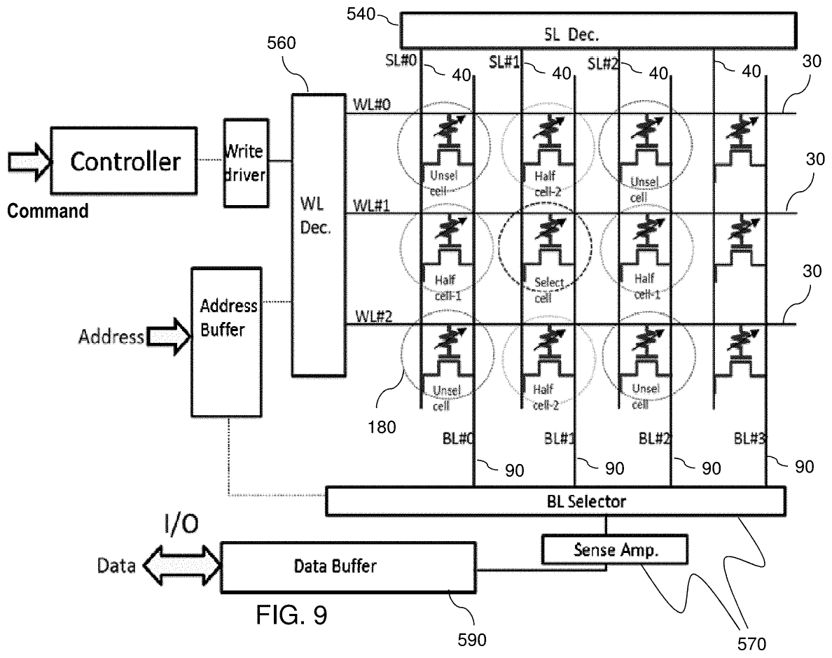

Referring to FIG. 9, a circuit diagram for a two-dimensional field effect transistor resistive memory array device according to an embodiment of the present disclosure is illustrated. In this case, each resistive memory cell 180 can be configured as an instance of the interfacial resistive memory gate stack field effect transistor of FIG. 2 or FIG. 7F. The word lines can comprise first electrically conductive lines 30 that include, or are electrically connected to, a row of gate electrodes 756. The bit lines can comprise second electrically conductive lines 90 that include, or are electrically connected to, a column of drain regions 734. The select lines can comprise third electrically conductive lines 40 that include, or are electrically connected to, a column of source lines 732.

In one embodiment, the semiconductor channel of each instance of the field effect transistor (which can be the interfacial resistive memory gate stack field effect transistor of FIG. 2 or FIG. 7) can be a horizontal surface portion of a semiconductor material layer located in, on, or over, a substrate. In one embodiment, the resistive memory device comprises a two-dimensional array of a plurality of instances of the field effect transistor.

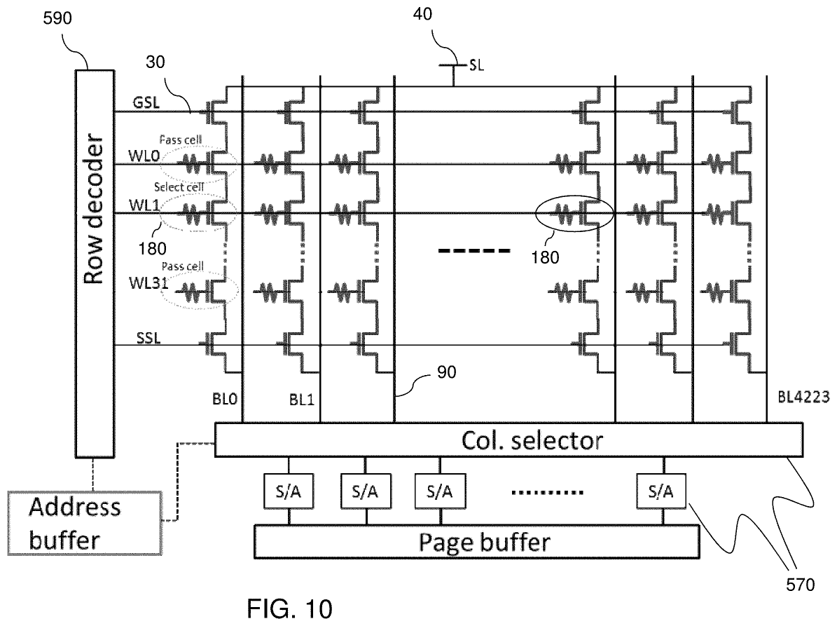

Referring to FIG. 10, a circuit diagram is illustrated for a two-dimensional or three-dimensional NAND resistive memory array device according to an embodiment of the present disclosure. Each resistive memory cell 180 can be configured as an instance of the interfacial resistive memory gate stack field effect transistor of FIG. 2 or FIG. 7F, or may be configured as an instance of a resistive memory cell in a three-dimensional NAND resistive memory array device to be described below. In this case, the resistive memory device can comprise a plurality of gate stacks located between a source region and a drain region. Each combination of a plurality of gate stacks and a semiconductor channel comprises a NAND string extending between a respective source region and a respective drain region. Each gate stack within the plurality of gate stacks overlies, along a vertical direction or along a horizontal direction, a respective portion of the semiconductor channel. Each gate stack within the plurality of gate stacks of a NAND string comprises a respective gate dielectric or a respective portion of a gate dielectric, a respective resistive memory material layer, and a respective gate electrode comprising a conductive material and located on the respective resistive memory material layer.

In one embodiment, the resistive memory device can be a two-dimensional NAND resistive memory array device, and each resistive memory cell 180 can have the same configuration as the interfacial resistive memory gate stack field effect transistor of FIG. 2 or FIG. 7F with a modification that a plurality of interfacial resistive memory gate stacks (752, 754, 756) overlie a semiconductor channel 711 located between a source region 732 and a drain region 734. The semiconductor channel 711 extends along a first horizontal direction within a semiconductor material layer. Each interfacial resistive memory gate stack (752, 754, 756) overlies a respective portion of the semiconductor channel 711. The plurality of gate electrodes 756 is laterally spaced apart thereamongst along the horizontal direction, which is the lengthwise direction of the semiconductor channel 711.

In one embodiment, the resistive memory device comprises a two-dimensional memory device. The two-dimensional memory device includes a one-dimensional array of a plurality of instances of the NAND string that are laterally spaced apart along a second horizontal direction. Each word line embodied as a respective first electrically conductive line 30 can be connected to a row of gate electrodes 756 that include one gate electrode 756 from each NAND string. Each bit line embodied as a respective second electrically conductive line 90 can be connected to a drain region 734 of a respective one of the NAND strings. Each select line embodied as a respective third electrically conductive line 40 can be connected to source regions 732 of a group of NAND strings that can be selected at the same time.

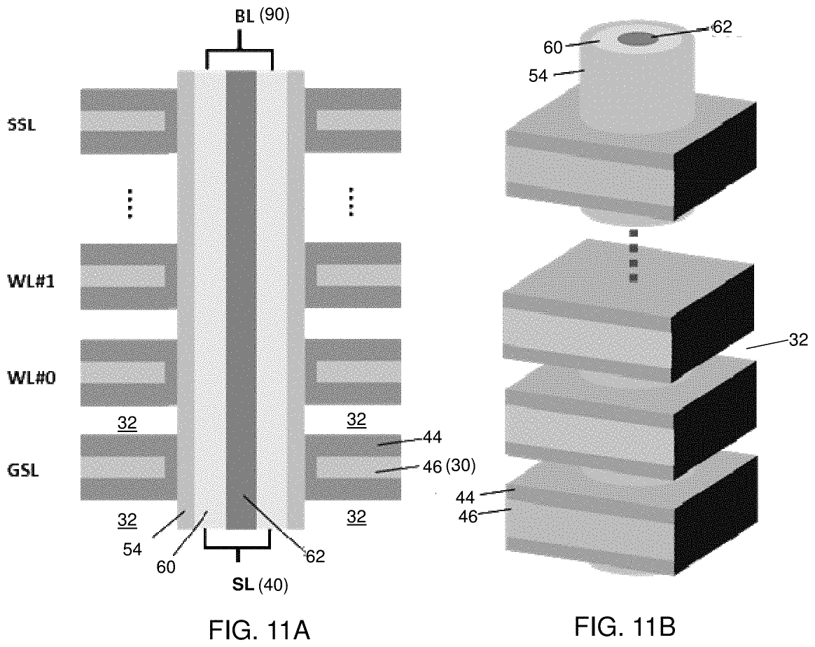

Referring to FIGS. 11A and 11B, a vertical NAND string is illustrated, which can be used to form a three-dimensional resistive memory array device according to an embodiment of the present disclosure.

An alternating stack of insulating layers 32 and sacrificial material layers can be formed over a substrate. Memory openings extending through the alternating stack can be formed by etching through the alternating stack in discrete areas, which may be circular areas or elliptical areas. The memory openings are filled with memory opening fill structures, each of which include, from outside to inside, a gate dielectric 54, a vertical semiconductor channel 60, and an optional dielectric core 62. The sacrificial material layers can be removed to form backside recesses, each of which laterally surrounds the memory opening fill structures (54, 60, 62) at a respective level. Each of the backside recesses can be filled with a resistive memory material layer 44 and a gate electrode 46, which functions as a first electrically conductive line 30. One end of each vertical semiconductor channel 60 can be connected to a respective bit line embodied as a respective second electrically conductive line 90 through a source region or a drain region. Another end of each vertical semiconductor channel 60 can be connected to a respective select electrode through the drain region or through the source region. The select electrode can comprise, or can be connected to, a third electrically conductive line 40.

In one embodiment, each vertical semiconductor channel 60 and a plurality of gate stacks (54, 44, 46) located thereupon comprises a NAND string extending between a source region and a drain region. A plurality of vertical NAND strings can be provided. Each vertical NAND string of the resistive memory device comprises a plurality of gate stacks (54, 44, 46) located between a respective source region and a respective drain region. In one embodiment, the source regions may be a single source region that is shared among a plurality of NAND strings. Each gate stack (54, 44, 46) within the plurality of gate stacks (54, 44, 46) laterally overlies a respective portion of the vertical semiconductor channel 60. Each gate stack (54, 44, 46) within the plurality of gate stacks (54, 44, 46) comprises a respective gate dielectric (a portion of 54), a respective resistive memory material layer 44 located on the respective gate dielectric 54, and a respective gate electrode 46 comprising a conductive material and located on the respective resistive memory material layer 44.

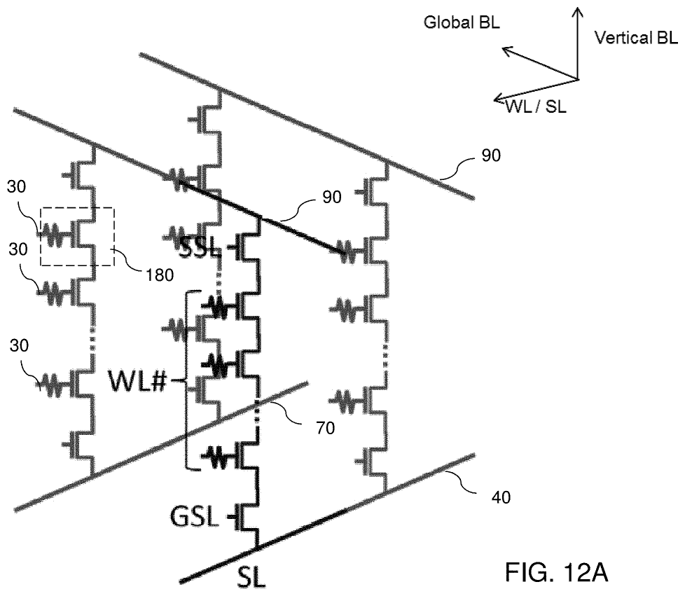

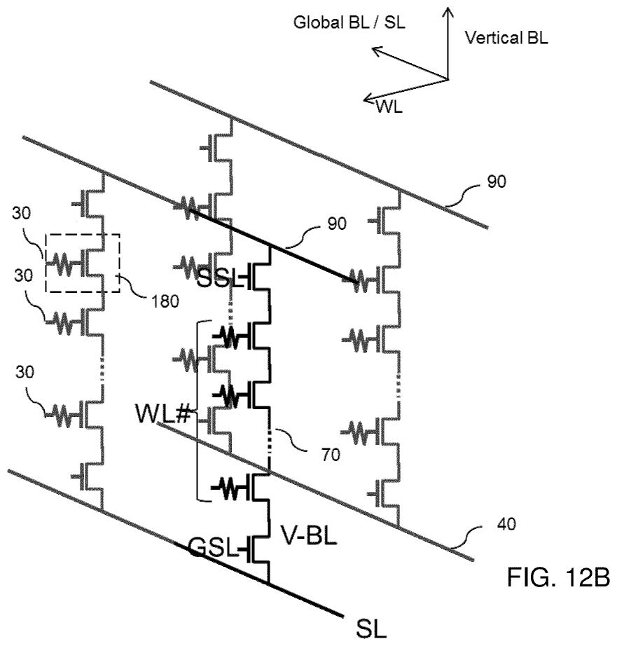

Referring to FIGS. 12A and 12B, schematic views for two embodiments of a three-dimensional NAND resistive memory array device of the present disclosure are illustrated. Each resistive memory cell 180 can be configured as an instance of a resistive memory cell that includes a portion of a gate dielectric 54, a resistive memory material layer 44, and an end portion of a gate electrode 46 that is a portion of a first electrically conducive line 30 that is proximal to the resistive memory material layer 44. In this case, the resistive memory device can comprise a plurality of gate stacks (54, 44, 46) located between a source region and a drain region. Each drain region can be located at an upper end of a vertical semiconductor channel 60, and each source region can be located at a lower end of a vertical semiconductor channel 60. Each vertical semiconductor channel 60 includes a vertically-extending portion and may optionally include a horizontally-extending portion. Each vertical semiconductor channel 60 has a doping of the first conductivity type, and the source regions and the drain regions have a doping of a second conductivity type that is the opposite of the first conductivity type.

Each combination of a plurality of gate stacks (54, 44, 46) and a vertical semiconductor channel 60 comprises a NAND string extending between a respective source region and a respective drain region. Each gate stack (54, 44, 46) within the plurality of gate stacks (54, 44, 46) overlies, along a horizontal direction, a respective portion of the vertical semiconductor channel 60. Each gate stack (54, 44, 46) within the plurality of gate stacks (54, 44, 46) of a NAND string comprises a respective portion of a gate dielectric 54, a respective resistive memory material layer 44 located on the respective portion of the gate dielectric 54, and a respective gate electrode 46 comprising a conductive material and located on the respective resistive memory material layer 44.

In one embodiment, the resistive memory device can be a three-dimensional NAND resistive memory array device, and the vertical semiconductor channel 60 extends along a vertical direction. Each gate stack (54, 44, 46), which can be an interfacial resistive memory gate stack, laterally overlies a respective portion of the semiconductor channel 711. The plurality of gate electrodes 46 is vertically spaced apart thereamongst along the vertical direction, which is the lengthwise direction of the vertical semiconductor channel 60.

In one embodiment, the resistive memory device comprises a three-dimensional memory device. Each combination of a vertical semiconductor channel 60 and a plurality of gate stacks (54, 44, 46) located thereupon comprises a NAND string extending between a source region and a drain region. The vertical semiconductor channel 60 of each vertical NAND string extends along a vertical direction, and each gate electrode 46 among a plurality of gate electrodes of each vertical NAND string can be located at different levels above a substrate that underlies the vertical semiconductor channel 60. The three-dimensional memory device can include a two-dimensional array of a plurality of instances of the vertical NAND string that are laterally spaced apart along horizontal directions. Each word line embodied as a first electrically conductive line 30 can be connected to a respective electrically conductive layer that incorporates a two-dimensional array of gate electrodes 46. In other words, each gate electrode 46 can be a portion of an electrically conductive layer 46. Each global bit line embodied as a respective second electrically conductive line 90 can be connected to drain regions of a respective set of NAND strings.

In one embodiment, a select line embodied as a respective third electrically conductive line 40 can be connected to source regions of each row of NAND strings that are connected to different global bit lines (which comprise the second electrically conductive lines 90) as illustrated in FIG. 12A. In this case, a column of NAND strings connected to a same global bit line (i.e., a same second electrically conductive line 90) can be connected to multiple third electrically conductive lines 40 that function as select lines. The word lines can be parallel to the select lines and may be shared between NAND strings that are connected to a different combination of a select line and a global bit line. A combination of a selected select line and a global bit line uniquely selects a vertical NAND string. Each interfacial resistive memory gate stack transistor cell 180 is accessed uniquely by selection of a select line, a word line, and a global bit line.

In another embodiment, each select line which comprises respective third electrically conductive line 40 can be connected to source regions of a row of NAND strings that are connected to a same second electrically conductive line 90 (that functions as a global bit line 90) as illustrated in FIG. 12B. In this case, a row of NAND strings connected to a same global bit line (which comprises the second electrically conductive line 90) can be connected to a same third electrically conductive line 40 that function as a select line. The word lines can laterally extend along a direction perpendicular to the lengthwise direction of the second electrically conductive lines 90 (that function as global bit lines) and the third electrically conductive lines 40 (that function as the select lines). Multiple word lines can be laterally spaced apart from one another at each word line level along the lengthwise direction of the second electrically conductive lines 90 (that function as global bit lines) and the third electrically conductive lines 40 (that function as the select lines). Thus, multiple vertical NAND strings connected to a same pair of a second electrically conductive line 90 (that functions as a global bit line) and a third electrically conductive line 40 (that functions as a select line) can be independently controlled by a respective vertical stack of word lines. A combination of a selected select line and a global bit line uniquely selects a row of vertical NAND strings. A selected word line can then uniquely access an interfacial resistive memory gate stack transistor cell 180 within the row of vertical NAND strings. Thus, each interfacial resistive memory gate stack transistor cell 180 is accessed uniquely by selection of a select line, a word line, and a global bit line.

In one embodiment, a source-level select gate electrode (GSL) can be provided adjacent to the source lines, which can comprise, or can be electrically connected to, the third electrically conductive lines 40. A drain-level select gate electrode (SSL) can be provided adjacent to the bit lines, which can comprise, or can be electrically connected to, the second electrically conductive lines 90.

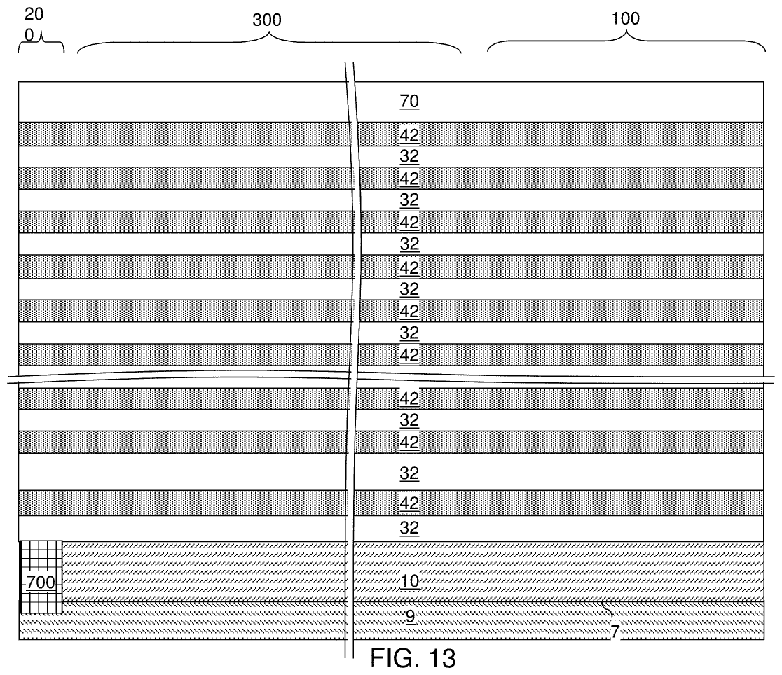

Referring to FIG. 13, a second exemplary structure according to a second embodiment of the present disclosure is illustrated, which can be used, for example, to fabricate a device structure containing vertical NAND resistive memory devices. The second exemplary structure includes a substrate (9, 10), which can be a semiconductor substrate. The substrate can include a substrate semiconductor material layer 9 and an optional semiconductor material layer 10. The substrate semiconductor material layer 9 maybe a semiconductor wafer or a semiconductor material layer, and can include at least one elemental semiconductor material (e.g., single crystal silicon wafer or layer), at least one III-V compound semiconductor material, at least one II-VI compound semiconductor material, at least one organic semiconductor material, or other semiconductor materials known in the art. The substrate can have a major surface 7, which can be, for example, a topmost surface of the substrate semiconductor material layer 9. The major surface 7 can be a semiconductor surface. In one embodiment, the major surface 7 can be a single crystalline semiconductor surface, such as a single crystalline semiconductor surface.

At least one semiconductor device 700 for a peripheral circuitry can be formed on a portion of the substrate semiconductor material layer 9. The at least one semiconductor device can include, for example, field effect transistors. The optional semiconductor material layer 10, if present, can be formed on the top surface of the substrate semiconductor material layer 9 prior to, or after, formation of the at least one semiconductor device 700 by deposition of a single crystalline semiconductor material, for example, by selective epitaxy. The deposited semiconductor material can be the same as, or can be different from, the semiconductor material of the substrate semiconductor material layer 9. The deposited semiconductor material can be any material that can be used for the semiconductor substrate layer 9 as described above. The single crystalline semiconductor material of the semiconductor material layer 10 can be in epitaxial alignment with the single crystalline structure of the substrate semiconductor material layer 9.

The region (i.e., area) of the at least one semiconductor device 700 is herein referred to as a peripheral device region 200. The region in which a memory array is subsequently formed is herein referred to as a memory array region 100. A contact region 300 for subsequently forming stepped terraces of electrically conductive layers can be provided between the memory array region 100 and the peripheral device region 200.

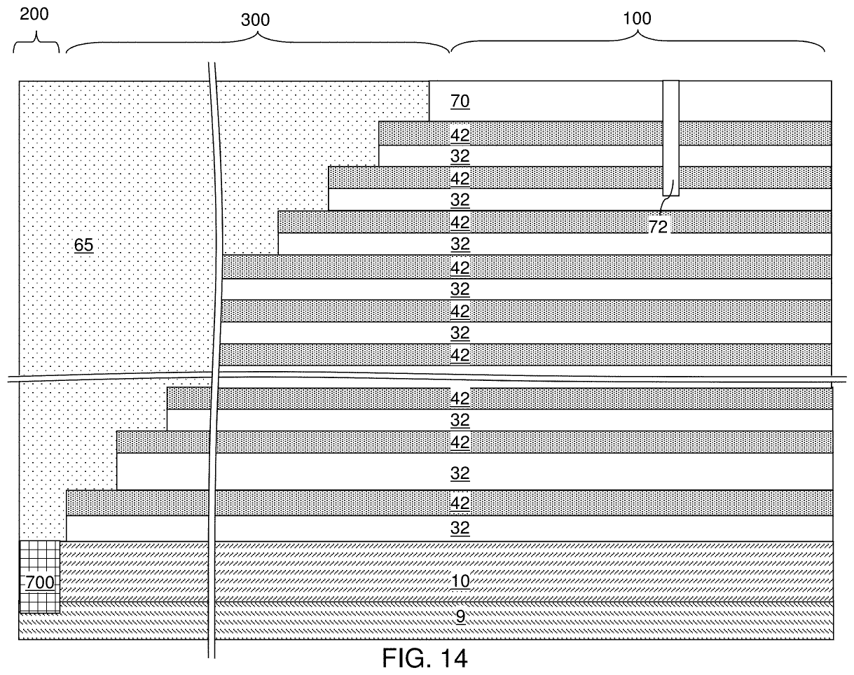

Referring to FIG. 14, a stack of an alternating plurality of first material layers (which can be insulating layers 32) and second material layers (which can be sacrificial material layer 42) is formed over the top surface of the substrate (9, 10). As used herein, a “material layer” refers to a layer including a material throughout the entirety thereof. As used herein, an alternating plurality of first elements and second elements refers to a structure in which instances of the first elements and instances of the second elements alternate. Each instance of the first elements that is not an end element of the alternating plurality is adjoined by two instances of the second elements on both sides, and each instance of the second elements that is not an end element of the alternating plurality is adjoined by two instances of the first elements on both ends. The first elements may have the same thickness thereamongst, or may have different thicknesses. The second elements may have the same thickness thereamongst, or may have different thicknesses. The alternating plurality of first material layers and second material layers may begin with an instance of the first material layers or with an instance of the second material layers, and may end with an instance of the first material layers or with an instance of the second material layers. In one embodiment, an instance of the first elements and an instance of the second elements may form a unit that is repeated with periodicity within the alternating plurality.

Each first material layer includes a first material, and each second material layer includes a second material that is different from the first material. In one embodiment, each first material layer can be an insulating layer 32, and each second material layer can be a sacrificial material layer. In this case, the stack can include an alternating plurality of insulating layers 32 and sacrificial material layers 42, and constitutes a prototype stack of alternating layers comprising insulating layers 32 and sacrificial material layers 42.

The stack of the alternating plurality is herein referred to as an alternating stack (32, 42). In one embodiment, the alternating stack (32, 42) can include insulating layers 32 composed of the first material, and sacrificial material layers 42 composed of a second material different from that of insulating layers 32. The first material of the insulating layers 32 can be at least one insulating material. As such, each insulating layer 32 can be an insulating material layer. Insulating materials that can be used for the insulating layers 32 include, but are not limited to, silicon oxide (including doped or undoped silicate glass), silicon nitride, silicon oxynitride, organosilicate glass (OSG), spin-on dielectric materials, dielectric metal oxides that are commonly known as high dielectric constant (high-k) dielectric oxides (e.g., aluminum oxide, hafnium oxide, etc.) and silicates thereof, dielectric metal oxynitrides and silicates thereof, and organic insulating materials. In one embodiment, the first material of the insulating layers 32 can be silicon oxide.

The second material of the sacrificial material layers 42 is a sacrificial material that can be removed selective to the first material of the insulating layers 32. As used herein, a removal of a first material is “selective to” a second material if the removal process removes the first material at a rate that is at least twice the rate of removal of the second material. The ratio of the rate of removal of the first material to the rate of removal of the second material is herein referred to as a “selectivity” of the removal process for the first material with respect to the second material.

The sacrificial material layers 42 may comprise an insulating material, a semiconductor material, or a conductive material. The second material of the sacrificial material layers 42 can be subsequently replaced with electrically conductive electrodes which can function, for example, as control gate electrodes of a vertical NAND device. Non-limiting examples of the second material include silicon nitride, an amorphous semiconductor material (such as amorphous silicon), and a polycrystalline semiconductor material (such as polysilicon). In one embodiment, the sacrificial material layers 42 can be spacer material layers that comprise silicon nitride or a semiconductor material including at least one of silicon and germanium.

In one embodiment, the insulating layers 32 can include silicon oxide, and sacrificial material layers can include silicon nitride sacrificial material layers. The first material of the insulating layers 32 can be deposited, for example, by chemical vapor deposition (CVD). For example, if silicon oxide is used for the insulating layers 32, tetraethyl orthosilicate (TEOS) can be used as the precursor material for the CVD process. The second material of the sacrificial material layers 42 can be formed, for example, CVD or atomic layer deposition (ALD).

The sacrificial material layers 42 can be suitably patterned so that conductive material portions to be subsequently formed by replacement of the sacrificial material layers 42 can function as electrically conductive electrodes, such as the control gate electrodes of the monolithic three-dimensional NAND string memory devices to be subsequently formed. The sacrificial material layers 42 may comprise a portion having a strip shape extending substantially parallel to the major surface 7 of the substrate.

The thicknesses of the insulating layers 32 and the sacrificial material layers 42 can be in a range from 20 nm to 50 nm, although lesser and greater thicknesses can be used for each insulating layer 32 and for each sacrificial material layer 42. The number of repetitions of the pairs of an insulating layer 32 and a sacrificial material layer (e.g., a control gate electrode or a sacrificial material layer) 42 can be in a range from 2 to 1,024, and typically from 8 to 256, although a greater number of repetitions can also be used. The top and bottom gate electrodes in the stack may function as the select gate electrodes. In one embodiment, each sacrificial material layer 42 in the alternating stack (32, 42) can have a uniform thickness that is substantially invariant within each respective sacrificial material layer 42.

Optionally, an insulating cap layer 70 can be formed over the alternating stack (32, 42). The insulating cap layer 70 includes a dielectric material that is different from the material of the sacrificial material layers 42. In one embodiment, the insulating cap layer 70 can include a dielectric material that can be used for the insulating layers 32 as described above. The insulating cap layer 70 can have a greater thickness than each of the insulating layers 32. The insulating cap layer 70 can be deposited, for example, by chemical vapor deposition. In one embodiment, the insulating cap layer 70 can be a silicon oxide layer.

Stepped surfaces are formed at a peripheral region of the alternating stack (32, 42), which is herein referred to as a terrace region. As used herein, “stepped surfaces” refer to a set of surfaces that include at least two horizontal surfaces and at least two vertical surfaces such that each horizontal surface is adjoined to a first vertical surface that extends upward from a first edge of the horizontal surface, and is adjoined to a second vertical surface that extends downward from a second edge of the horizontal surface. A stepped cavity is formed within the volume from which portions of the alternating stack (32, 42) are removed through formation of the stepped surfaces. A “stepped cavity” refers to a cavity having stepped surfaces.

The terrace region is formed in the contact region 300, which is located between the memory array region 100 and the peripheral device region 200 containing the at least one semiconductor device for the peripheral circuitry. The stepped cavity can have various stepped surfaces such that the horizontal cross-sectional shape of the stepped cavity changes in steps as a function of the vertical distance from the top surface of the substrate (9, 10). In one embodiment, the stepped cavity can be formed by repetitively performing a set of processing steps. The set of processing steps can include, for example, an etch process of a first type that vertically increases the depth of a cavity by one or more levels, and an etch process of a second type that laterally expands the area to be vertically etched in a subsequent etch process of the first type. As used herein, a “level” of a structure including alternating plurality is defined as the relative position of a pair of a first material layer and a second material layer within the structure.

Each sacrificial material layer 42 other than a topmost sacrificial material layer 42 within the alternating stack (32, 42) laterally extends farther than any overlying sacrificial material layer 42 within the alternating stack (32, 42) in the terrace region. The terrace region includes stepped surfaces of the alternating stack (32, 42) that continuously extend from a bottommost layer within the alternating stack (32, 42) to a topmost layer within the alternating stack (32, 42).

Each vertical step of the stepped surfaces can have the height of one or more pairs of an insulating layer 32 and a sacrificial material layer. In one embodiment, each vertical step can have the height of a single pair of an insulating layer 32 and a sacrificial material layer 42. In another embodiment, multiple “columns” of staircases can be formed along a first horizontal direction hd1 such that each vertical step has the height of a plurality of pairs of an insulating layer 32 and a sacrificial material layer 42, and the number of columns can be at least the number of the plurality of pairs. Each column of staircase can be vertically offset among one another such that each of the sacrificial material layers 42 has a physically exposed top surface in a respective column of staircases. In the illustrative example, two columns of staircases are formed for each block of memory stack structures to be subsequently formed such that one column of staircases provide physically exposed top surfaces for odd-numbered sacrificial material layers 42 (as counted from the bottom) and another column of staircases provide physically exposed top surfaces for even-numbered sacrificial material layers (as counted from the bottom). Configurations using three, four, or more columns of staircases with a respective set of vertical offsets among the physically exposed surfaces of the sacrificial material layers 42 may also be used. Each sacrificial material layer 42 has a greater lateral extent, at least along one direction, than any overlying sacrificial material layers 42 such that each physically exposed surface of any sacrificial material layer 42 does not have an overhang. In one embodiment, the vertical steps within each column of staircases may be arranged along the first horizontal direction hd1, and the columns of staircases may be arranged along a second horizontal direction hd2 that is perpendicular to the first horizontal direction hd1. In one embodiment, the first horizontal direction hd1 may be perpendicular to the boundary between the memory array region 100 and the contact region 300.

A retro-stepped dielectric material portion 65 (i.e., an insulating fill material portion) can be formed in the stepped cavity by deposition of a dielectric material therein. For example, a dielectric material such as silicon oxide can be deposited in the stepped cavity. Excess portions of the deposited dielectric material can be removed from above the top surface of the insulating cap layer 70, for example, by chemical mechanical planarization (CMP). The remaining portion of the deposited dielectric material filling the stepped cavity constitutes the retro-stepped dielectric material portion 65. As used herein, a “retro-stepped” element refers to an element that has stepped surfaces and a horizontal cross-sectional area that increases monotonically as a function of a vertical distance from a top surface of a substrate on which the element is present. If silicon oxide is used for the retro-stepped dielectric material portion 65, the silicon oxide of the retro-stepped dielectric material portion 65 may, or may not, be doped with dopants such as B, P, and/or F.

Optionally, drain select level isolation structures 72 can be formed through the insulating cap layer 70 and a subset of the sacrificial material layers 42 located at drain select levels. The drain select level isolation structures 72 can be formed, for example, by forming drain select level isolation trenches and filling the drain select level isolation trenches with a dielectric material such as silicon oxide. Excess portions of the dielectric material can be removed from above the top surface of the insulating cap layer 70.

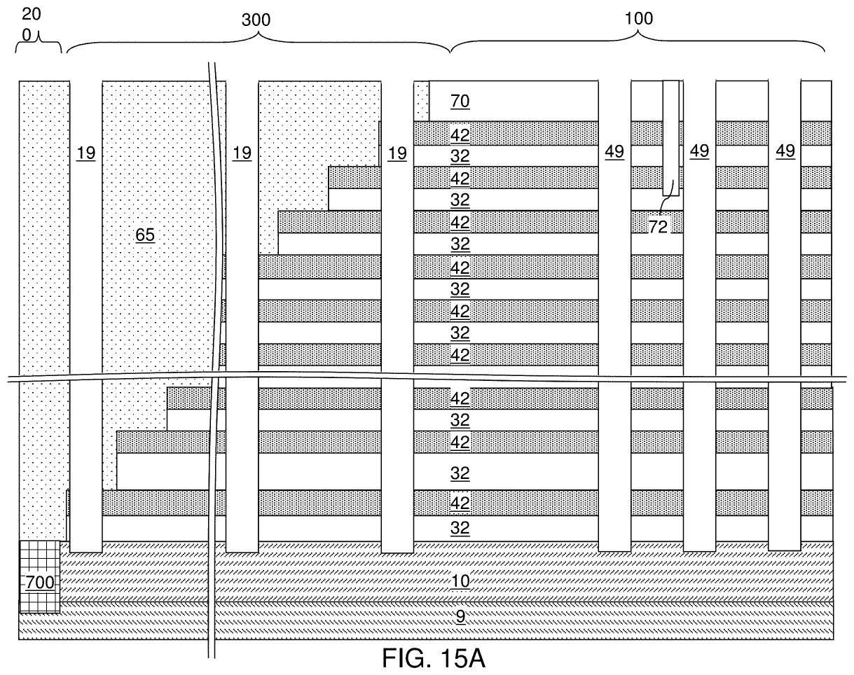

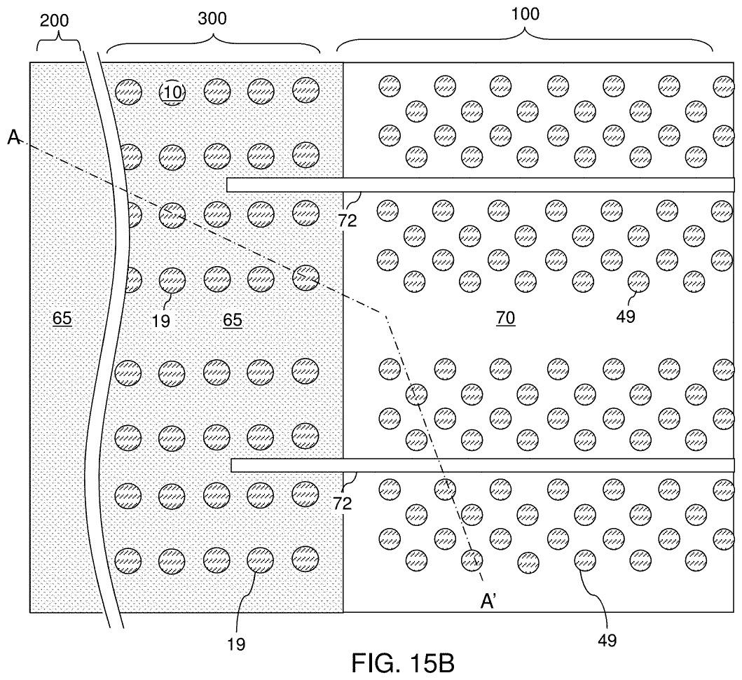

Referring to FIGS. 15A and 15B, a lithographic material stack (not shown) including at least a photoresist layer can be formed over the insulating cap layer 70 and the retro-stepped dielectric material portion 65, and can be lithographically patterned to form openings therein. The openings include a first set of openings formed over the memory array region 100 and a second set of openings formed over the contact region 300. The pattern in the lithographic material stack can be transferred through the insulating cap layer 70 or the retro-stepped dielectric material portion 65, and through the alternating stack (32, 42) by at least one anisotropic etch that uses the patterned lithographic material stack as an etch mask. Portions of the alternating stack (32, 42) underlying the openings in the patterned lithographic material stack are etched to form memory openings 49 and support openings 19. As used herein, a “memory opening” refers to a structure in which memory elements, such as a memory stack structure, is subsequently formed. As used herein, a “support opening” refers to a structure in which a support structure (such as a support pillar structure) that mechanically supports other elements is subsequently formed. The memory openings 49 are formed through the insulating cap layer 70 and the entirety of the alternating stack (32, 42) in the memory array region 100. The support openings 19 are formed through the retro-stepped dielectric material portion 65 and the portion of the alternating stack (32, 42) that underlie the stepped surfaces in the contact region 300.

The memory openings 49 extend through the entirety of the alternating stack (32, 42). The support openings 19 extend through a subset of layers within the alternating stack (32, 42). The chemistry of the anisotropic etch process used to etch through the materials of the alternating stack (32, 42) can alternate to optimize etching of the first and second materials in the alternating stack (32, 42). The anisotropic etch can be, for example, a series of reactive ion etches. The sidewalls of the memory openings 49 and the support openings 19 can be substantially vertical, or can be tapered. The patterned lithographic material stack can be subsequently removed, for example, by ashing.

The memory openings 49 and the support openings 19 can extend from the top surface of the alternating stack (32, 42) to at least the horizontal plane including the topmost surface of the semiconductor material layer 10. In one embodiment, an overetch into the semiconductor material layer 10 may be optionally performed after the top surface of the semiconductor material layer 10 is physically exposed at a bottom of each memory opening 49 and each support opening 19. The overetch may be performed prior to, or after, removal of the lithographic material stack. In other words, the recessed surfaces of the semiconductor material layer 10 may be vertically offset from the un-recessed top surfaces of the semiconductor material layer 10 by a recess depth. The recess depth can be, for example, in a range from 1 nm to 50 nm, although lesser and greater recess depths can also be used. The overetch is optional, and may be omitted. If the overetch is not performed, the bottom surfaces of the memory openings 49 and the support openings 19 can be coplanar with the topmost surface of the semiconductor material layer 10.

Each of the memory openings 49 and the support openings 19 may include a sidewall (or a plurality of sidewalls) that extends substantially perpendicular to the topmost surface of the substrate. A two-dimensional array of memory openings 49 can be formed in the memory array region 100. A two-dimensional array of support openings 19 can be formed in the contact region 300. The substrate semiconductor material layer 9 and the semiconductor material layer 10 collectively constitutes a substrate (9, 10), which can be a semiconductor substrate. Alternatively, the semiconductor material layer 10 may be omitted, and the memory openings 49 and the support openings 19 can be extend to a top surface of the substrate semiconductor material layer 9.

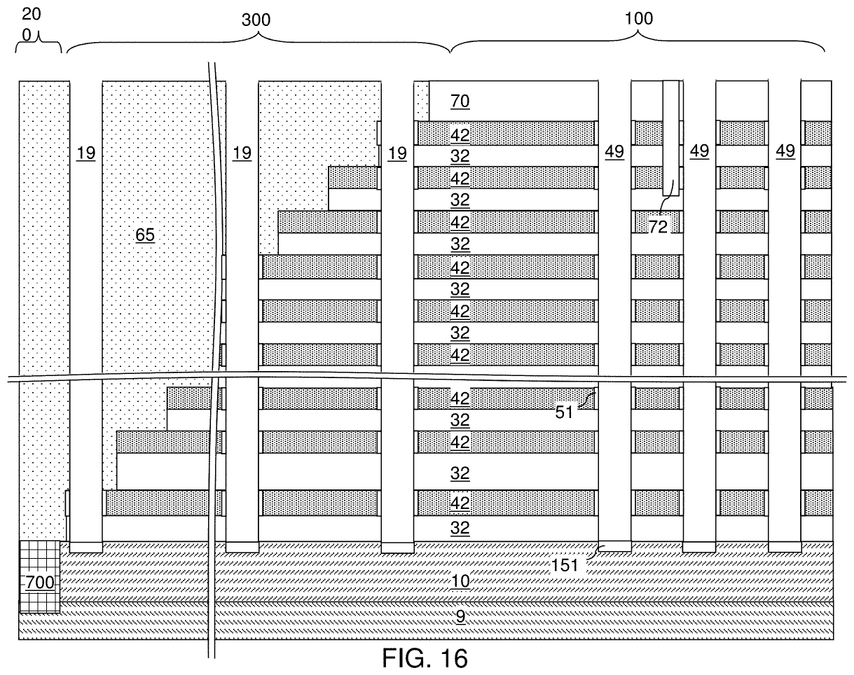

Referring to FIG. 16, an oxidation process can be optionally performed to convert surface portions of sacrificial material layers 42 into sacrificial annular dielectric structures 51. For example, if the sacrificial material layers 42 include silicon nitride, the sacrificial annular dielectric structures 51 can include silicon oxide formed by oxidation of surface portions of the silicon nitride material around each memory opening 49 and around each support opening 19. Sacrificial planar dielectric structures 151 can be formed by conversion of surface portions of the semiconductor material layer into dielectric material portions underneath each memory opening 49 and underneath each support opening. The thickness of each sacrificial annular dielectric structure 51 and each sacrificial planar dielectric structure 151 can be in a range from 1 nm to 10 nm, such as from 2 nm to 6 nm, although lesser and greater thicknesses can also be used.

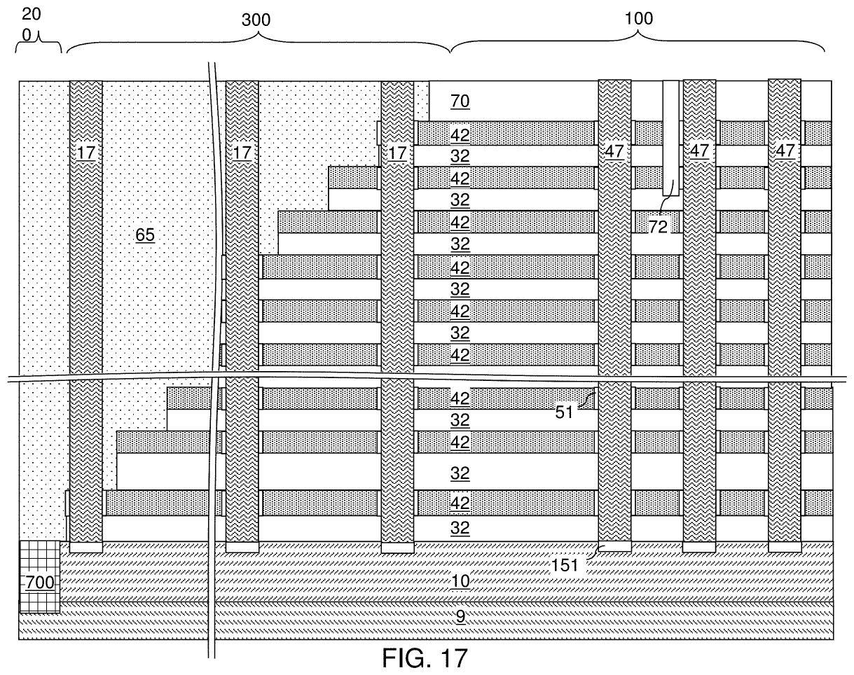

Referring to FIG. 17, a sacrificial fill material can be deposited in the memory openings 49 and in the support openings 17. The sacrificial fill material comprises a material that can be removed selective to the insulating layers 32, the annular dielectric structures 51, and the sacrificial planar dielectric structures 151. For example, the sacrificial fill material can include a semiconductor material such as amorphous silicon, polysilicon, or a silicon-germanium alloy material. Alternatively, the sacrificial fill material can include borosilicate glass or organosilicate glass. Excess portions of the sacrificial fill material can be removed from above the top surface of the insulating cap layer 70 by a planarization process such as chemical mechanical planarization. Each remaining portion of the sacrificial fill material in a memory opening 49 constitutes a sacrificial memory opening fill material portion 47. Each remaining portion of the sacrificial fill material in a support opening 19 constitutes a sacrificial support opening fill material portion 17.

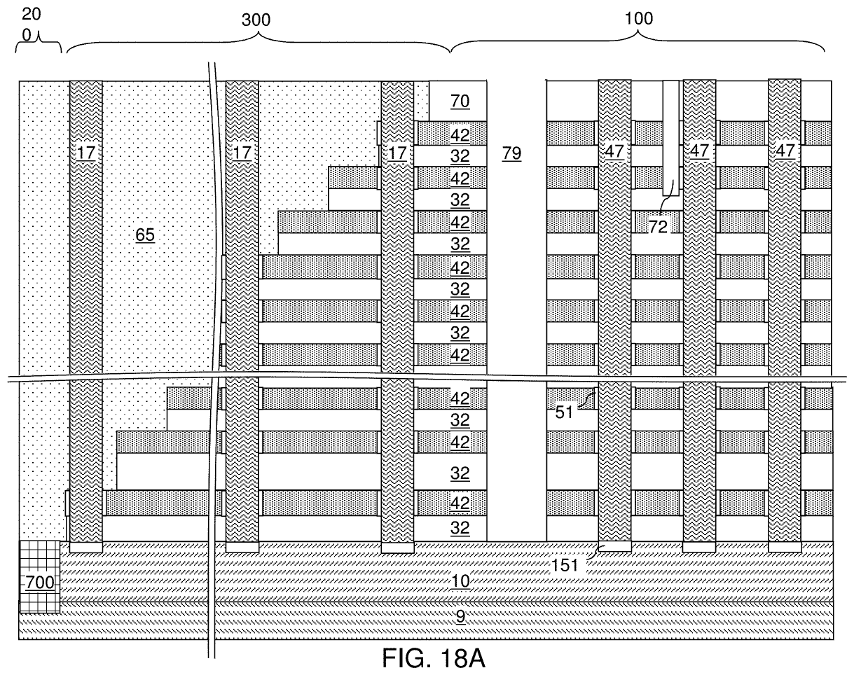

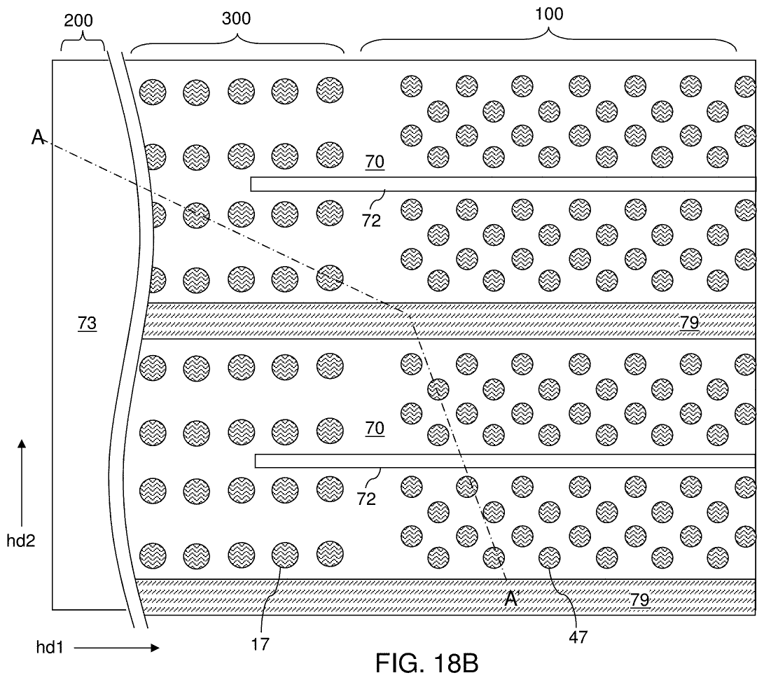

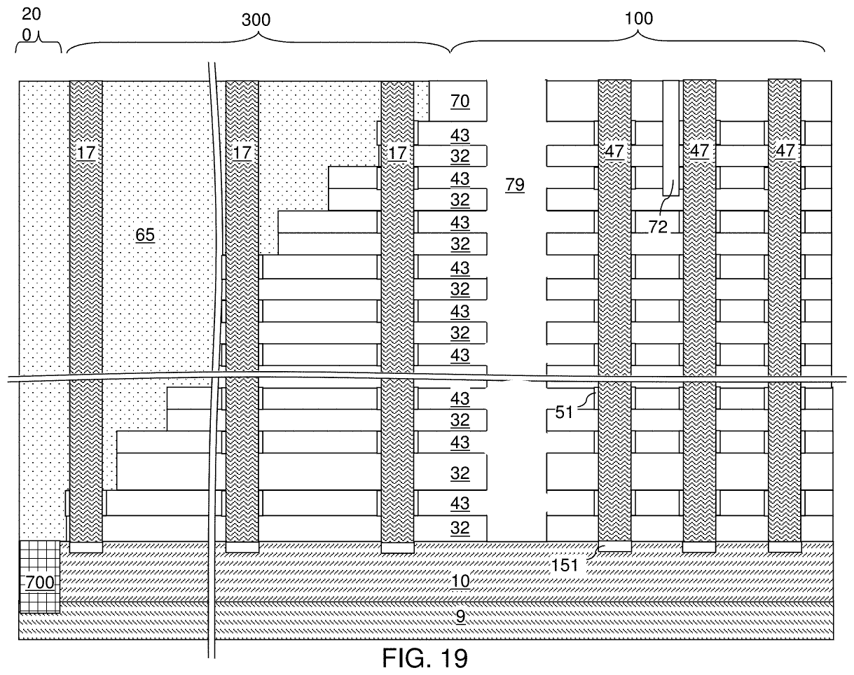

Referring to FIGS. 18A and 18B, a photoresist layer (not shown) can be applied over the insulating cap layer 70 and lithographically patterned to form openings in areas between clusters of sacrificial memory opening fill material portions 47. The pattern in the photoresist layer can be transferred through the insulating cap layer 70, the alternating stack (32, 42) and/or the retro-stepped dielectric material portion 65 using an anisotropic etch to form backside trenches 79, which vertically extend from the top surface of the insulating cap layer 70 at least to the top surface of the substrate (9, 10), and laterally extend through the memory array region 100 and the contact region 300.

In one embodiment, the backside trenches 79 can laterally extend along a first horizontal direction hd1 and can be laterally spaced apart among one another along a second horizontal direction hd2 that is perpendicular to the first horizontal direction hd1. The memory stack structures 55 can be arranged in rows that extend along the first horizontal direction hd1. The drain select level isolation structures 72 can laterally extend along the first horizontal direction hd1. Each backside trench 79 can have a uniform width that is invariant along the lengthwise direction (i.e., along the first horizontal direction hd1). Each drain select level isolation structure 72 can have a uniform vertical cross-sectional profile along vertical planes that are perpendicular to the first horizontal direction hd1 that is invariant with translation along the first horizontal direction hd1. Multiple rows of memory stack structures 55 can be located between a neighboring pair of a backside trench 79 and a drain select level isolation structure 72, or between a neighboring pair of drain select level isolation structures 72. In one embodiment, the backside trenches 79 can include a source contact opening in which a source contact via structure can be subsequently formed. The photoresist layer can be removed, for example, by ashing.

Referring to FIG. 19, an etchant that selectively etches the second material of the sacrificial material layers 42 with respect to the first material of the insulating layers 32 can be introduced into the backside trenches 79, for example, using an etch process. Backside recesses 43 are formed in volumes from which the sacrificial material layers 42 are removed. The removal of the second material of the sacrificial material layers 42 can be selective to the first material of the insulating layers 32, the material of the retro-stepped dielectric material portion 65, the semiconductor material of the semiconductor material layer 10, and the material of the sacrificial annular dielectric structures 51. In one embodiment, the sacrificial material layers 42 can include silicon nitride, and the insulating layers 32, the retro-stepped dielectric material portion 65, and the sacrificial annular dielectric structures 51 can include silicon oxide.

The etch process that removes the second material selective to the first material and the sacrificial annular dielectric structures 51 can be a wet etch process using a wet etch solution, or can be a gas phase (dry) etch process in which the etchant is introduced in a vapor phase into the backside trenches 79. For example, if the sacrificial material layers 42 include silicon nitride, the etch process can be a wet etch process in which the second exemplary structure is immersed within a wet etch tank including phosphoric acid, which etches silicon nitride selective to silicon oxide, silicon, and various other materials used in the art. The sacrificial support opening fill structures 17, the retro-stepped dielectric material portion 65, and the sacrificial memory opening fill structures 47 provide structural support while the backside recesses 43 are present within volumes previously occupied by the sacrificial material layers 42.

Each backside recess 43 can be a laterally extending cavity having a lateral dimension that is greater than the vertical extent of the cavity. In other words, the lateral dimension of each backside recess 43 can be greater than the height of the backside recess 43. A plurality of backside recesses 43 can be formed in the volumes from which the second material of the sacrificial material layers 42 is removed. The memory openings in which the memory stack structures 55 are formed are herein referred to as front side openings or front side cavities in contrast with the backside recesses 43. In one embodiment, the memory array region 100 comprises an array of monolithic three-dimensional NAND strings having a plurality of device levels disposed above the substrate (9, 10). In this case, each backside recess 43 can define a space for receiving a respective word line of the array of monolithic three-dimensional NAND strings.

Each of the plurality of backside recesses 43 can extend substantially parallel to the top surface of the substrate (9, 10). A backside recess 43 can be vertically bounded by a top surface of an underlying insulating layer 32 and a bottom surface of an overlying insulating layer 32. In one embodiment, each backside recess 43 can have a uniform height throughout.

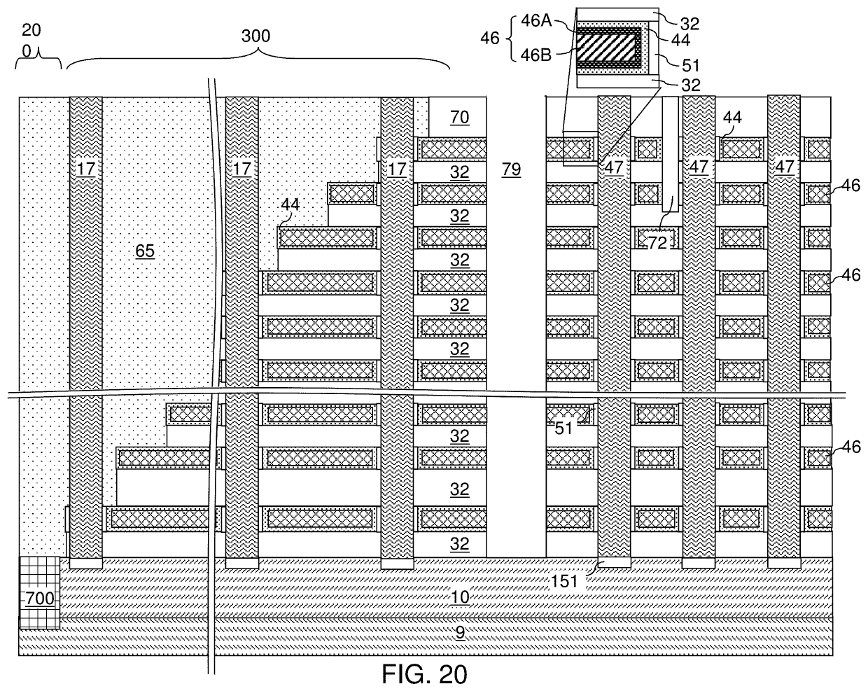

Referring to FIG. 20, a resistive memory material layer 44 can be formed by a conformal deposition process. The resistive memory material layer 44 can have the same material composition and the same thickness as the continuous memory material layer 754L described above. The memory material layer 44 can be formed, for example, by atomic layer deposition or by chemical vapor deposition. The resistive memory material layer 44 can be formed in the backside recesses 43 and on a sidewall of the backside trench 79. The resistive memory material layer 44 can be formed directly on horizontal surfaces of the insulating layers 32 and sidewalls of the sacrificial annular dielectric structures 51. A backside cavity is present within the portion of each backside trench 79 that is not filled with the resistive memory material layer 44.

Referring to FIG. 20, at least one conductive material can be conformally deposited in the backside recesses 43. For example, a metallic barrier layer 46A can be deposited in the backside recesses 43. The metallic barrier layer 46A includes an electrically conductive metallic material that can function as a diffusion barrier layer and/or adhesion promotion layer for a metallic fill material to be subsequently deposited. The metallic barrier layer 46A can include a conductive metallic nitride material such as TiN, TaN, WN, or a stack thereof, or can include a conductive metallic carbide material such as TiC, TaC, WC, or a stack thereof. In one embodiment, the metallic barrier layer 46A can be deposited by a conformal deposition process such as chemical vapor deposition (CVD) or atomic layer deposition (ALD). The thickness of the metallic barrier layer 46A can be in a range from 2 nm to 8 nm, such as from 3 nm to 6 nm, although lesser and greater thicknesses can also be used. In one embodiment, the metallic barrier layer 46A can consist essentially of a conductive metal nitride such as TiN.

A metal fill material is deposited in the plurality of backside recesses 43, on the sidewalls of the at least one the backside trench 79, and over the top surface of the insulating cap layer 70 to form a metallic fill material layer 46B. The metallic fill material can be deposited by a conformal deposition method, which can be, for example, chemical vapor deposition (CVD), atomic layer deposition (ALD), electroless plating, electroplating, or a combination thereof. In one embodiment, the metallic fill material layer 46B can consist essentially of at least one elemental metal. The at least one elemental metal of the metallic fill material layer 46B can be selected, for example, from tungsten, cobalt, ruthenium, titanium, and tantalum. In one embodiment, the metallic fill material layer 46B can consist essentially of a single elemental metal. In one embodiment, the metallic fill material layer 46B can be deposited using a fluorine-containing precursor gas such as WF₆. In one embodiment, the metallic fill material layer 46B can be a tungsten layer including a residual level of fluorine atoms as impurities. The metallic fill material layer 46B is spaced from the insulating layers 32 and the memory stack structures 55 by the metallic barrier layer 46A, which is a metallic barrier layer that blocks diffusion of fluorine atoms therethrough.

A plurality of electrically conductive layers 46 can be formed in the plurality of backside recesses 43, and a continuous metallic material layer (not shown) can be formed on the sidewalls of each backside trench 79 and over the insulating cap layer 70. Each electrically conductive layer 46 includes a portion of the metallic barrier layer 46A and a portion of the metallic fill material layer 46B that are located between a vertically neighboring pair of dielectric material layers such as a pair of insulating layers 32. The continuous metallic material layer includes a continuous portion of the metallic barrier layer 46A and a continuous portion of the metallic fill material layer 46B that are located in the backside trenches 79 or above the insulating cap layer 70. Each sacrificial material layer 42 can be replaced with an electrically conductive layer 46. A backside cavity is present in the portion of each backside trench 79 that is not filled with the resistive memory material layer 44 and the continuous metallic material layer.

The deposited metallic material of the continuous electrically conductive material layer is etched back from the sidewalls of each backside trench 79 and from above the insulating cap layer 70, for example, by an isotropic wet etch, an anisotropic dry etch, or a combination thereof. Each remaining portion of the deposited metallic material in the backside recesses 43 constitutes an electrically conductive layer 46. Each electrically conductive layer 46 can be a conductive line structure, which can be a portion of, and/or electrically connected to, a respective one of the first electrically conductive lines 30 of a random access memory device 500. Thus, the sacrificial material layers 42 are replaced with the electrically conductive layers 46.

Each electrically conductive layer 46 can function as a combination of a plurality of control gate electrodes located at a same level and a word line electrically interconnecting, i.e., electrically connecting, the plurality of gate electrodes located at the same level. The plurality of gate electrodes within each electrically conductive layer 46 are the control gate electrodes for the vertical memory devices to be subsequently formed. In other words, each electrically conductive layer 46 can be a word line that functions as a common control gate electrode for the plurality of vertical memory devices.

In one embodiment, the removal of the continuous electrically conductive material layer can be selective to the material of the resistive memory material layer 44. In this case, vertical portions of the resistive memory material layer 44 in each baskside trench 79 can be adjoined to horizontal portions of the resistive memory material layer 44 filling the volumes of the backside recesses 43. In another embodiment, the removal of the continuous electrically conductive material layer may not be selective to the material of the resistive memory material layer 44. In this case, a discrete resistive memory material layer 44 can be present at each level of the electrically conductive layers 46, and can be vertically spaced among one another. A backside cavity is present within each backside trench 79.

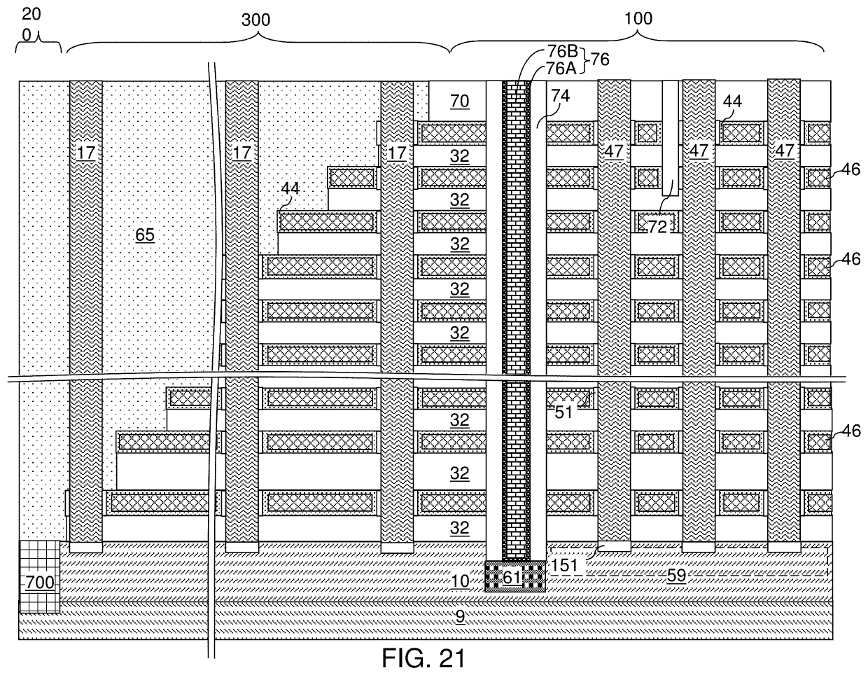

Referring to FIG. 21, an insulating material layer can be formed in the backside trenches 79 and over the insulating cap layer 70 by a conformal deposition process. Exemplary conformal deposition processes include, but are not limited to, chemical vapor deposition and atomic layer deposition. The insulating material layer includes an insulating material such as silicon oxide, silicon nitride, a dielectric metal oxide, an organosilicate glass, or a combination thereof. In one embodiment, the insulating material layer can include silicon oxide. The insulating material layer can be formed, for example, by low pressure chemical vapor deposition (LPCVD) or atomic layer deposition (ALD). The thickness of the insulating material layer can be in a range from 1.5 nm to 60 nm, although lesser and greater thicknesses can also be used. The insulating material layer can be formed directly on surfaces of the resistive memory material layer 44 and directly on the sidewalls of the electrically conductive layers 46.

An anisotropic etch is performed to remove horizontal portions of the insulating material layer from above the insulating cap layer 70 and at the bottom of each backside trench 79. Each remaining portion of the insulating material layer constitutes an insulating spacer 74. A backside cavity is present within a volume surrounded by each insulating spacer 74. A top surface of the semiconductor material layer 10 can be physically exposed at the bottom of each backside trench 79.

A source region 61 can be formed at a surface portion of the semiconductor material layer 10 under each backside cavity by implantation of electrical dopants into physically exposed surface portions of the semiconductor material layer 10. Each source region 61 is formed in a surface portion of the substrate (9, 10) that underlies a respective opening through the insulating spacer 74. Due to the straggle of the implanted dopant atoms during the implantation process and lateral diffusion of the implanted dopant atoms during a subsequent activation anneal process, each source region 61 can have a lateral extent greater than the lateral extent of the opening through the insulating spacer 74.

An upper portion of the semiconductor material layer 10 that extends between the source region 61 and the plurality of sacrificial memory opening fill material portions 47 constitutes a horizontal semiconductor channel 59 for a plurality of field effect transistors to be subsequently formed. The horizontal semiconductor channel 59 is connected to multiple vertical semiconductor channels 60 extends between a source region 61 and an area that underlies an adjacent set of sacrificial memory opening fill material portions 47. Each source region 61 is formed in an upper portion of the semiconductor substrate (9, 10).

A backside contact via structure 76 can be formed within each backside cavity. Each contact via structure 76 can fill a respective cavity. The contact via structures 76 can be formed by depositing at least one conductive material in the remaining unfilled volume (i.e., the backside cavity) of the backside trench 79. For example, the at least one conductive material can include a conductive liner 76A and a conductive fill material portion 76B. The conductive liner 76A can include a conductive metallic liner such as TiN, TaN, WN, TiC, TaC, WC, an alloy thereof, or a stack thereof. The thickness of the conductive liner 76A can be in a range from 3 nm to 30 nm, although lesser and greater thicknesses can also be used. The conductive fill material portion 76B can include a metal or a metallic alloy. For example, the conductive fill material portion 76B can include W, Cu, Al, Co, Ru, Ni, an alloy thereof, or a stack thereof.

The at least one conductive material can be planarized using the insulating cap layer 70 overlying the alternating stack (32, 46) as a stopping layer. If chemical mechanical planarization (CMP) process is used, the insulating cap layer 70 can be used as a CMP stopping layer. Each remaining continuous portion of the at least one conductive material in the backside trenches 79 constitutes a backside contact via structure 76. The backside contact via structure 76 extends through the alternating stack (32, 46), and contacts a top surface of the source region 61.

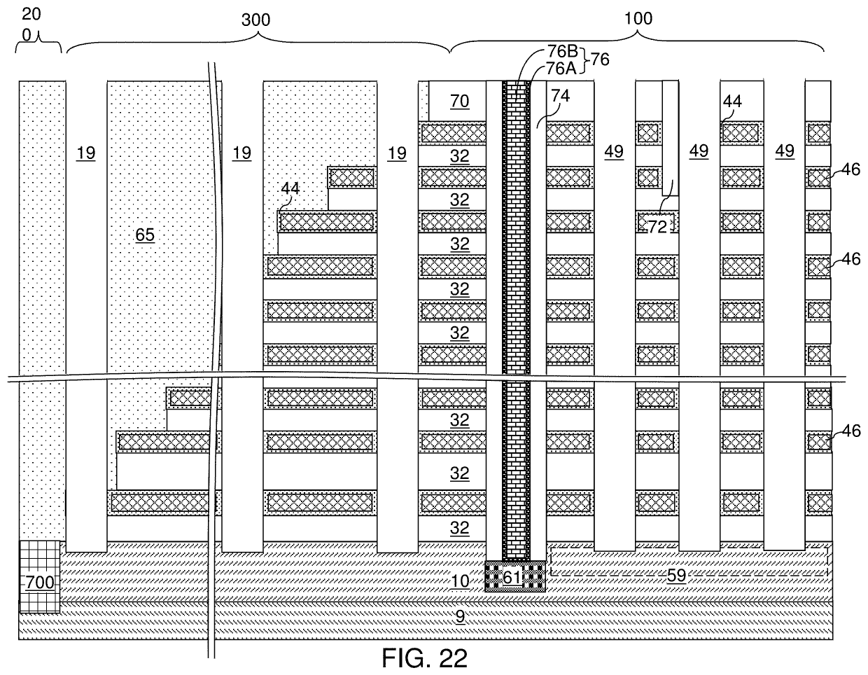

Referring to FIG. 22, the sacrificial fill material of the sacrificial memory opening fill material portions 47 and the sacrificial support opening fill material portions 17 can be removed selective to the sacrificial annular dielectric structures 51 and the sacrificial planar dielectric structures 151. For example, if the sacrificial fill material of the sacrificial memory opening fill material portions 47 and the sacrificial support opening fill material portions 17 includes amorphous silicon, polysilicon, or a silicon-germanium alloy material, a wet etch process using hot trimethyl-2 hydroxyethyl ammonium hydroxide (“hot TMY”) or tetramethyl ammonium hydroxide (TMAH) can be used to remove the sacrificial fill material selective to the materials of the sacrificial annular dielectric structures 51 and the sacrificial planar dielectric structures 151.

Subsequently, another etch process can be performed to remove the sacrificial annular dielectric structures 51 and the sacrificial planar dielectric structures 151 selective to the materials of the resistive memory material layers 44 and the semiconductor material layer 10. For example, if the sacrificial annular dielectric structures 51 and the sacrificial planar dielectric structures 151 include silicon oxide, a wet etch using dilute hydrofluoric acid can be used to remove the sacrificial annular dielectric structures 51 and the sacrificial planar dielectric structures 151 selective to the resistive memory material layers 44 and the semiconductor material layer 10. A memory opening 49 is formed in each volume from which a sacrificial memory opening fill material portion 47, an underlying sacrificial planar dielectric structure 151, and a set of sacrificial annular dielectric structures 51 are removed. A support opening 19 is formed in each volume from which a sacrificial support opening fill material portion 17, an underlying sacrificial planar dielectric structure 151, and a set of sacrificial annular dielectric structures 51 are removed.

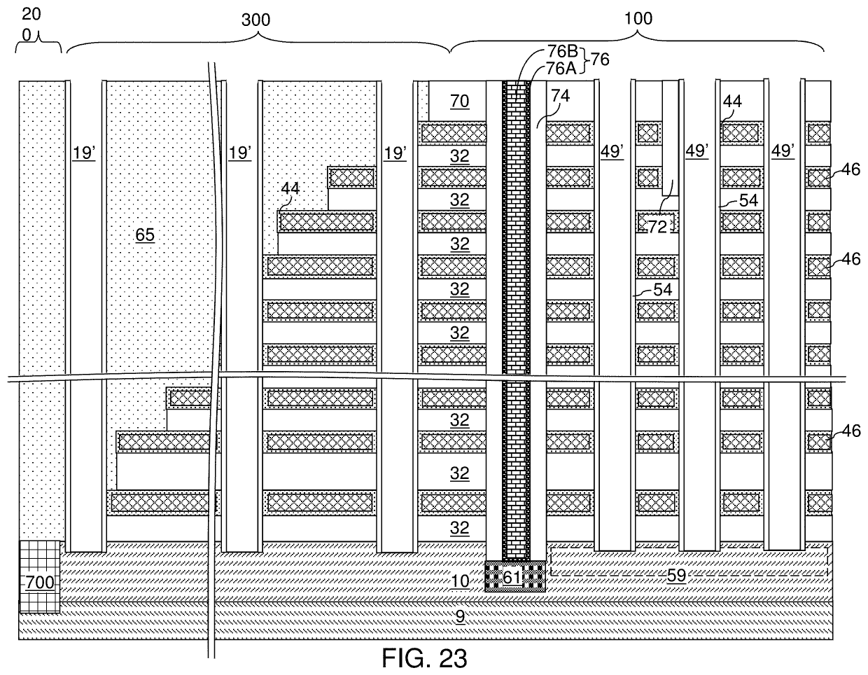

Referring to FIG. 23, a gate dielectric 54 is formed at a periphery of each memory opening 49 and each support opening 19. The gate dielectrics 54 can have the same material composition and the same thickness as the continuous gate dielectric layer 752L described above. In one embodiment, the gate dielectrics 54 can include hafnium oxide. The gate dielectrics 54 can be formed by conformally depositing a gate dielectric material layer and a sacrificial protective liner (such as an amorphous silicon line having a thickness in a range from 3 nm to 15 nm), anisotropically etching the sacrificial protective liner and the gate dielectric material layer to remove horizontal portions of the sacrificial protective liner and the gate dielectric material layer, and by removing remaining portions of the sacrificial protective liner selective to the remaining portions of the gate dielectric material layer. Each remaining cylindrical portion of the gate dielectric material layer constitutes a gate dielectric 54. Each gate dielectric can vertically extend through the entirety of the alternating stack of insulating layers 32 and electrically conductive layers 46.

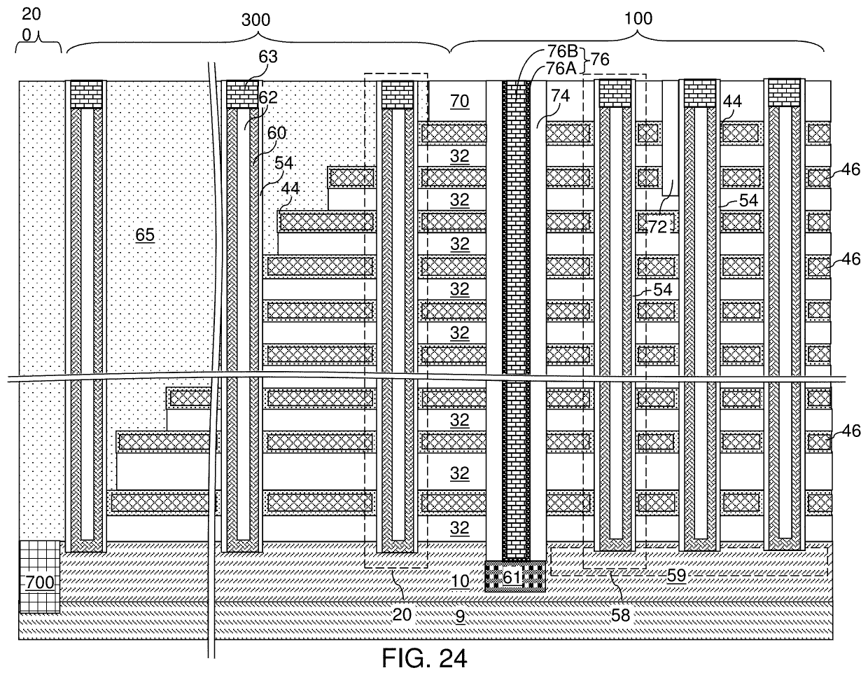

Referring to FIG. 24, a semiconductor material having a doping of the first conductivity type can be conformally deposited in the memory cavities 49′ and the support cavities 19′ to form a continuous semiconductor channel material layer. The continuous semiconductor channel material layer can be deposited directly on physically exposed surfaces of the semiconductor material layer 10 that includes horizontal semiconductor channels 59. A dielectric material such as a doped silicate glass can be conformally deposited in remaining volumes of the memory cavities 49′ and the support cavities 19′ to form a dielectric fill material layer.

Excess portions of the dielectric fill material layer and the continuous semiconductor channel material layer can be removed from above the horizontal plane including the top surface of the insulating cap layer 70 by a planarization process such as a recess etch. The recess etch can be continued to vertically recess top surfaces of the remaining portions of the dielectric fill material layer and the continuous semiconductor channel material layer below the horizontal plane including the top surface of the insulating cap layer 70. Each remaining portion of the continuous semiconductor channel material layer constitutes a vertical semiconductor channel 60, and each remaining portion of the dielectric fill material layer constitutes a dielectric core 62. The top surfaces of the vertical semiconductor channels 60 and the dielectric cores 62 can be located between the horizontal plane including the top surface of the insulating cap layer 70 and the horizontal plane including the bottom surface of the insulating cap layer 70.

Recess regions overlying the vertical semiconductor channels 60 and the dielectric cores 62 can be filled with a doped semiconductor material having a doping of the second conductivity type. Excess portions of the doped semiconductor material can be removed from above the horizontal plane including the top surface of the insulating cap layer 70. Each remaining portion of the doped semiconductor material constitutes a drain region 63. Each combination of a gate dielectric 54, a vertical semiconductor channel 60, a dielectric core 62, and a drain region 63 that fills a memory opening 49 constitutes a memory opening fill structure 58. Each combination of a gate dielectric 54, a vertical semiconductor channel 60, a dielectric core 62, and a drain region 63 that fills a support opening 19 constitutes a support pillar structure 20. Each support pillar structure 20 can include a same set of components as a memory opening fill structure 58. However, electrical contacts are not made to the drain regions 63 within the support pillar structures 20 so that the support pillar structures 20 function as dummy structures that are not electrically active.

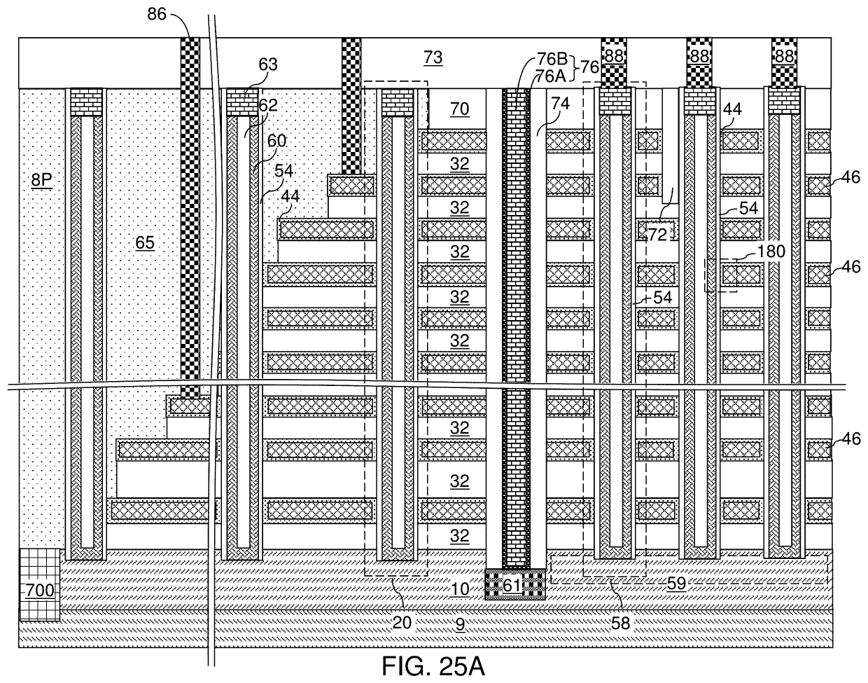

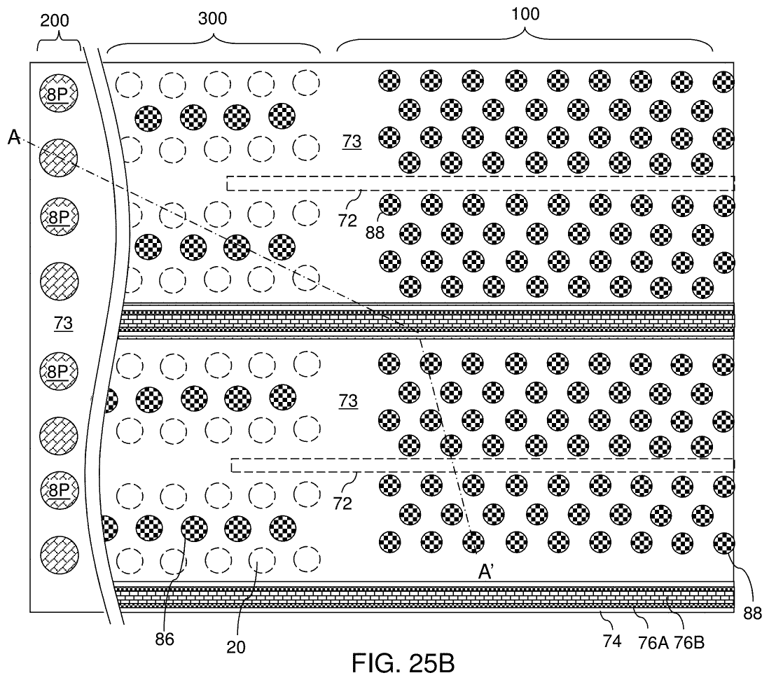

Referring to FIGS. 25A and 25B, a contact level dielectric layer 73 can be formed over the insulating cap layer 70, the memory opening fill structures 58, and the support pillar structures 20. The contact level dielectric layer 73 includes a dielectric material such as silicon oxide. The contact level dielectric layer 73 can have a thickness in a range from 50 nm to 500 nm, although lesser and greater thicknesses can also be used.

Contact via structures (88, 86, 8P) can be formed through the contact level dielectric layer 73, and optionally through the retro-stepped dielectric material portion 65. For example, drain contact via structures 88 can be formed through the contact level dielectric layer 73 on each drain region 63. Word line contact via structures 86 can be formed on the electrically conductive layers 46 through the contact level dielectric layer 73, and through the retro-stepped dielectric material portion 65. Peripheral device contact via structures 8P can be formed through the retro-stepped dielectric material portion 65 directly on respective nodes of the peripheral devices.

The second exemplary structure can include a three-dimensional array of resistive memory cells 180. Each resistive memory cell 180 includes a portion of a vertical semiconductor channel 60 located between a source region 61 and a drain region 63, a portion of a gate dielectric 54 located on the vertical semiconductor channel 60, a cylindrical portion of a resistive memory material layer 44, and a cylindrical portion of an electrically conductive layer 46 that laterally surrounds the cylindrical portion of the resistive memory material layer 44. The gate dielectric 54 is shared among a vertical string of resistive memory cells 180 located on a same vertical semiconductor channel. Each resistive memory material layer 44 is shared among a two-dimensional array of resistive memory cells 180 located at the same level as a respective electrically conductive layer 46.

In one embodiment, each source region 60 may be connected to a respective select line, which can be a third electrically conductive line 40. Alternatively or additionally, the bottommost one of the electrically conductive layers 46 may be connected to a respective source select line to select a set of NAND strings among multiple sets of NAND strings that are laterally spaced apart by the backside trenches 79. In this case, the bottommost one of the electrically conductive layers functions as a source select gate electrode. Additionally or alternatively, at least one topmost one of the electrically conductive layers 46 may be used as drain select gate electrodes to further select a subset of NAND strings among one set of NAND strings located between a neighboring pair of backside trenches 79. In this case, each of the at least one topmost one of the electrically conductive layers 46 functions as a drain select gate electrode.

The three-dimensional resistive memory device including the NAND strings of resistive memory cells 180 can be operated in the following manner. In an erase operation, all resistive memory cells 180 in a selected set of NAND strings between a neighboring pair of backside trenches can be programmed into a “set” state or a low resistance state by applying 0 V to word lines that laterally surround the selected set of NAND strings among the electrically conductive layers 46, electrically floating (by disconnecting any external voltage supply) each of the source select gate electrode and at least one drain select gate electrode (if any), and applying a negative set voltage −V_set to each of the source region 61 and the drain regions 63 through a respective source select line (which may include, or be electrically connected to, a third electrically conductive line 40) and through bit lines (which may be, or be electrically connected to, a set of second electrically conductive lines 90). The negative set voltage −V_set is selected to enable simultaneous programming of all resistive memory cells 180 within the selected set of NAND strings into the set state. Word lines that laterally surround unselected sets of NAND strings among the electrically conductive layers 46 can be electrically biased at the negative set voltage −V_set to prevent an erase operation in unselected sets (or “blocks”) of NAND strings.

In a program operation, portions of the vertical semiconductor channels 60 overlying the source select gate electrode and the source regions 61 can be electrically disconnected by applying 0 V to all source select gate electrodes. A positive turn-on bias voltage Vdd may be applied to the source regions 61. The bit line connected to the selected resistive memory cell 180 is biased at 0 V. All other bit lines that are not connected to the selected resistive memory cell 180 are biased at the positive turn-on bias voltage Vdd. All NAND strings in unselected subset (finger) of NAND strings can be turned off by applying 0 V to the drain select gate electrode(s) located outside the selected subset of NAND strings. The NAND strings in the selected subset of NAND strings are connected to a respective bit line by applying the positive turn-on bias voltage Vdd to the drain select gate electrode(s) connected to the selected subset of NAND strings. The portion of the vertical semiconductor channel 60 including the selected memory cell 180 and overlying the source select gate electrode is biased at 0 V by the bit line connected to the selected memory cell. Each portion of the vertical semiconductor channels 60 not including the selected memory cell 180 and located within the selected subset of NAND strings is biased at the positive turn-on bias voltage Vdd. A selected word line connected to the selected resistive memory cell 180 is biased at a positive reset programming voltage V_reset, and all other word lines are biased at a pass voltage, which is not positive enough to induce a reset programming at proximate resistive memory cells 180. Thus, the reset programming operation proceeds only at the selected resistive memory cell 180 at which a voltage differential of V_reset is present between the selected word line (i.e., the selected electrically conductive layer 46) and the selected vertical semiconductor channel 60, while all other resistive memory cells 180 are provided with a lesser voltage differential across a respective electrically conductive layer 46 and a respective vertical semiconductor channel 60 than is necessary to program a resistive memory cell 180. The pass voltage may be applied to all word lines outside of the selected set of NAND strings. The pass voltage may be an intermediate voltage between the positive turn-on bias voltage Vdd and 0 V, and is insufficient to induce any programming.

In a read operation, all bit lines can be biased at a bit line read voltage Vbl, which is a positive voltage having a lesser magnitude than the reset voltage V_reset. The bit line read voltage Vbl can be the same as the positive drain read bias voltage Vd of FIG. 6C. All source regions 61 can be biased at 0 V. Only a selected subset of NAND strings is electrically activated by applying positive turn-on bias voltage Vdd to the source select gate electrode and the at least one drain select gate electrode that control the selected subset of NAND strings. All unselected subsets of NAND strings are turned off by applying 0 V to the respective source select gate electrode and the respective drain select gate electrode(s). The word line that electrically biases the selected resistive memory cell 180, i.e., the selected word line, is biased at a positive read bias voltage V_read, which can be the same as the positive read bias voltage V_read of FIG. 6C and is also referred to a reference voltage. All other word lines controlling the selected set of NAND strings are biased at a read pass voltage V_rp that is more positive than the positive read bias voltage V_read. The read pass voltage V_rp is high enough to turn on each adjacent portion of vertical semiconductor channels 60 without triggering any changes in the resistive state. The portion of the vertical semiconductor channel 60 within the selected resistive memory element 180 may, or may not, be turned on depending on the resistive state of the resistive memory material layer 44 within the selective resistive memory element 180. Thus, the threshold voltage for the field effect transistor is modulated by the interfacial effects of the resistive memory material layer (754 or 44). The resistive state of the selected resistive memory element 180 can be sensed by the magnitude of the electrical current that passes through the selected bit line.

The resistive memory devices of the various embodiments enable a low voltage operation such that the maximum operational voltage has a magnitude less than 10 V. The endurance of the resistive memory devices of the various embodiments is expected to be at least 1,000 cycles, and may be greater than 10,000 cycles. The resistive memory device of the various embodiments is compatible with multi-memory-cell-per-level configuration in which two or more memory cells can be formed per each level of the electrically conductive layers and per memory opening. The switching time for the resistive memory devices of the various embodiments is expected to be less than 100 nanoseconds. The resistive memory devices of the various embodiments may be manufactured in a two-dimensional array configuration of a three-dimensional array configuration. The resistive memory devices of the various embodiments provide current amplification by using a field effect transistor of which the effective threshold voltage is controlled by the resistive state of a resistive memory material layer (754 or 44). Thus, the resistive memory device of the various embodiments provides sufficient electrical current for current sensing by normal sensing circuitry, and enables device scaling for resistive memory devices.

Although the foregoing refers to particular preferred embodiments, it will be understood that the claims are not so limited. Various modifications may be made to the disclosed embodiments and that such modifications are intended to be within the scope of the claims. Compatibility is presumed among all embodiments that are not alternatives of one another. The word “comprise” or “include” contemplates all embodiments in which the word “consist essentially of” or the word “consists of” replaces the word “comprise” or “include,” unless explicitly stated otherwise. Where an embodiment using a particular structure and/or configuration is illustrated in the present disclosure, it is understood that the claims may be practiced with any other compatible structures and/or configurations that are functionally equivalent provided that such substitutions are not explicitly forbidden or otherwise known to be impossible to one of ordinary skill in the art. All of the publications, patent applications and patents cited herein are incorporated herein by reference in their entirety.

What is claimed is:

1. A resistive memory device comprising at least one field effect transistor, wherein the field effect transistor comprises:
a semiconductor channel located between a source region and a drain region; and
a gate stack comprising a gate dielectric located on a surface of the semiconductor channel, a resistive memory material layer located on the gate dielectric, and a gate electrode located on the resistive memory material layer and comprising a conductive material.

2. The resistive memory device of claim 1, wherein the resistive memory material layer comprises an electrically conductive metal oxide material whose resistivity is configured to be switched by at least one of oxygen ion and/or oxygen vacancy diffusion in response to an application of an electric field thereto.

3. The resistive memory device of claim 2, wherein the electrically conductive metal oxide material comprises a titanium oxide material including oxygen vacancies.

4. The resistive memory device of claim 1, wherein:
the resistive memory device comprises a plurality of gate stacks including the gate stack and at least one additional gate stack located between the source region and the drain region;
each gate stack within the plurality of gate stacks overlies a respective portion of the semiconductor channel;
each gate stack within the plurality of gate stacks comprises a respective gate dielectric or a respective portion of a gate dielectric, a respective resistive memory material layer, and a respective gate electrode comprising a conductive material and located on the respective resistive memory material layer.

5. The resistive memory device of claim 4, wherein the plurality of gate stacks and the semiconductor channel comprises a NAND string extending between the source region and the drain region.

6. The resistive memory device of claim 5, wherein:
the semiconductor channel extends along a vertical direction; and
each gate electrode of the plurality of gate electrodes is located at different levels above a substrate that underlies the semiconductor channel.

7. The resistive memory device of claim 6, wherein the resistive memory device comprises a three-dimensional memory device that includes a two-dimensional array of a plurality of instances of the NAND string.

8. The resistive memory device of claim 5, wherein:
the semiconductor channel extends along a horizontal direction within a semiconductor material layer; and
the plurality of gate electrodes is laterally spaced apart thereamongst along a horizontal direction.

9. The resistive memory device of claim 8, wherein the resistive memory device comprises a two-dimensional memory device that includes a one-dimensional array of a plurality of instances of the NAND string that are laterally spaced apart along another horizontal direction.

10. The resistive memory device of claim 1, wherein the gate dielectric, the resistive memory material layer, and the gate electrode extends along the semiconductor channel from an edge of the source region to an edge of the drain region.

11. The resistive memory device of claim 10, wherein the semiconductor channel is a horizontal surface portion of a semiconductor material layer located in, on, or over a substrate.

12. The resistive memory device of claim 10, wherein the resistive memory device comprises a two-dimensional array of a plurality of instances of the field effect transistor.

13. A method of operating a resistive memory device, comprising:
providing the resistive memory device of claim 1;
programming the resistive memory material layer into a resistive state selected from a reset state and a set state, wherein the resistive memory material layer has a higher resistance and provides a lower capacitance between the gate electrode and the semiconductor channel in a reset state than in a set state; and
determining the resistive state of the resistive memory material layer by measuring a magnitude of a source-to-drain current under a predetermined drain bias voltage to the drain region and under a predetermined read bias voltage to the gate electrode.

14. The method of claim 13, wherein the resistive memory material layer is programmed into the reset state by applying a more positive voltage to the gate electrode than a voltage applied to the semiconductor channel while the source region and the drain region are biased at a same active region bias voltage.

15. The method of claim 13, wherein the resistive memory material layer is programmed into the set state by applying a more negative voltage to the gate electrode than a voltage applied to the semiconductor channel while the source region and the drain region are biased at a same active region bias voltage.

16. A method of forming a semiconductor structure, comprising:
forming an alternating stack of insulating layers and sacrificial material layers over a substrate;
forming a memory opening through the alternating stack;
forming a sacrificial memory opening fill structure through the memory opening;
forming backside recesses by removing the sacrificial material layers selective to the insulating layers;
forming a resistive memory material layer and an electrically conductive layer within each backside recess;
physically exposing sidewalls of the resistive memory material layers by removing the sacrificial memory opening fill structure;
forming a gate dielectric on the sidewalls of the resistive memory material layers and on sidewalls of the insulating layers; and forming a vertical semiconductor channel on the gate dielectric.

17. The method of claim 16, wherein:
the resistive memory material layer comprises an electrically conductive metal oxide material whose resistivity is configured to be switched by at least one of oxygen ion and/or oxygen vacancy diffusion in response to an application of an electric field thereto; and
the gate dielectric comprises a metal oxide dielectric material.

18. The method of claim 16, further comprising:
forming a backside trench extending through the alternating stack; and
introducing an isotropic etchant that etches a material of the sacrificial material layers selective to a material of the insulating layers into the backside trench, wherein the sacrificial material layers are etched selective to the insulating layers to provide the backside recesses.

19. The method of claim 16, further comprising:
forming a source region in a semiconductor material layer located in, or over the substrate; and
forming a drain region in an upper region of the memory opening after formation of the vertical semiconductor channel.

20. The method of claim 16, further comprising:
forming a terrace region by patterning the alternating stack, wherein each sacrificial material layer other than a topmost sacrificial material layer within the alternating stack laterally extends farther than any overlying sacrificial material layers within the alternating stack;
forming a retro-stepped dielectric material portion over the terrace region by depositing a dielectric material over the terrace region; and
forming support pillar structures through the retro-stepped dielectric material portion and portions of the alternating stack that underlie the stepped surfaces.
